(19) United States
(12) Patent Application Publication
(10) Pub. No.: US 2009/0253075 A1
(43) Pub. Date: Oct. 8, 2009

(54) POSITIVE RESIST COMPOSITION, AND METHOD OF FORMING RESIST PATTERN

(75) Inventors: Takeyoshi Mimura, Kawasaki-shi (JP); Akiya Kawaue, Kawasaki-shi (JP)

Correspondence Address: KNOBBE MARTENS OLSON & BEAR LLP, 2040 MAIN STREET, FOURTEENTH FLOOR, IRVINE, CA, 92614, US

(73) Assignee: Tokyo Ohka Kogyo Co., Ltd., Kawasaki-shi (JP)

(21) Appl. No.: 12/306,376

(22) PCT Filed: Apr. 20, 2007
(86) PCT No.: PCT/JP2007/058623

§ 371 Date: Dec. 23, 2008

(30) Foreign Application Priority Data
Jun. 30, 2006 (JP) 2006-181564

(51) Int. Cl. G03F 7/20; G03F 7/039

(52) U.S. Cl. 430/285.1; 430/326

(57) ABSTRACT

A positive resist composition including a resin component (A) which exhibits increased solubility in an alkali developing solution under action of acid and an acid-generator component (B) which generates acid upon exposure,
the resin component (A) including a structural unit (a1) derived from hydroxystyrene, a structural unit (a2) represented by general formula (a2-1) or (a2-2) shown below, and a structural unit (a3) represented by general formula (a3-1) or (a3-2) shown below.

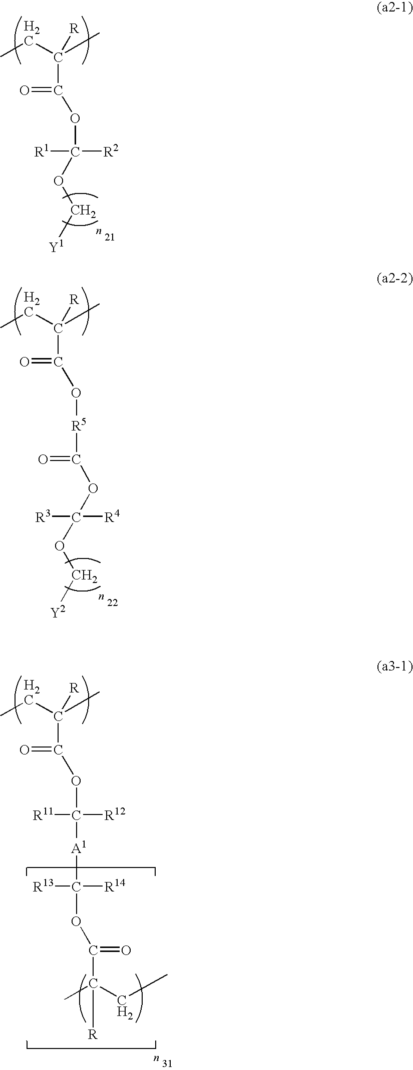

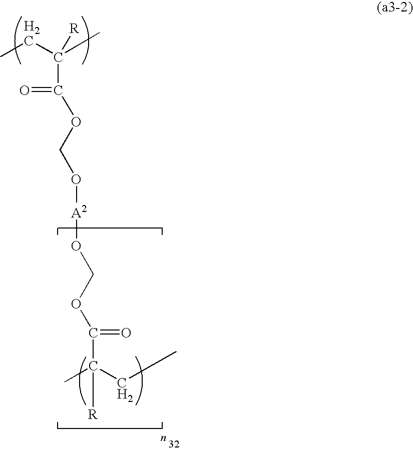

### TECHNICAL FIELD

The present invention relates to a positive resist composition and a method of forming a resist pattern.

Priority is claimed on Japanese Patent Application No. 2006-181564, filed Jun. 30, 2006, the content of which is incorporated herein by reference.

### BACKGROUND ART

In photolithography techniques, for example, a resist film composed of a resist composition is formed on a substrate, and the resist film is subjected to selective exposure of radial rays such as light or electron beam through a photomask having a predetermined pattern, followed by development, thereby forming a resist pattern having a predetermined shape on the resist film. A resist composition in which the exposed portions become soluble in a developing solution is called a positive-type, and a resist composition in which the exposed portions become insoluble in a developing solution is called a negative-type.

In recent years, in the production of semiconductor elements and liquid crystal display elements, advances in lithography techniques have lead to rapid progress in the field of pattern miniaturization. Typically, these miniaturization techniques involve shortening the wavelength of the exposure light. Conventionally, ultraviolet radiation typified by g-line and i-line radiation has been used, but nowadays KrF excimer lasers (248 nm) have been introduced, and ArF excimer lasers (193 nm) are now also starting to be introduced. Furthermore, research is also being conducted into lithography techniques that use exposure light source having a wavelength shorter than these excimer lasers, such as F₂ excimer lasers (157 nm), extreme ultraviolet radiation (EUV), electron beam, and X ray.

Reproduction of patterns with very fine dimensions requires resist materials with high resolution. As such resist materials, chemically amplified resist compositions are used, which include a base resin and an acid generator that generates acid upon exposure. For example, a chemically amplified positive resist contains a resin component in which the alkali solubility increases by the action of an acid and an acid generator component that generates acid upon exposure, and when an acid is generated from the acid generator by exposure in the formation of a resist pattern, the exposed portions become alkali soluble.

Typically, resins such as polyhydroxystyrene (PHS) based resins in which the hydroxyl groups have been protected with an acid-dissociable, dissolution inhibiting group or resins having structural units derived from (meth)acrylic acid within the main chain (namely, an acrylic-based resin) in which the carboxyl groups have been protected with an acid dissociable dissolution inhibiting group are used as resin components of chemically amplified positive resist compositions. Examples of used acid dissociable dissolution inhibiting groups include: so-called acetal groups such as chain-like ether groups typified by a 1-ethoxyethyl group, and cyclic ether groups typified by a tetrahydropyranyl group; tertiary alkyl groups typified by a tert-butyl group; and tertiary alkoxycarbonyl groups typified by a tert-butoxycarbonyl group (for example, refer to Patent Document 1).

Here, the term “(meth)acrylic acid” is a generic term that includes either or both of acrylic acid having a hydrogen atom bonded to the α-position and methacrylic acid having a methyl group bonded to the α-position. The term “(meth)acrylate ester” is a generic term that includes either or both of the acrylate ester having a hydrogen atom bonded to the α-position and the metacrylate ester having a methyl group bonded to the α-position. The term “(meth)acrylate” is a generic term that includes either or both of the acrylate having a hydrogen atom bonded to the α-position and the methacrylate having a methyl group bonded to the α-position.

[Patent Document 1] Japanese Unexamined Patent Application, First Publication No. 2002-341538

### DISCLOSURE OF INVENTION

### Problems to be Solved by the Invention

In recent years, further improvements in resolution have been required along with progress in the miniaturization of resist patterns.

The present invention takes the above circumstances into consideration, with an object of providing a positive resist composition which is capable of forming a resist pattern with excellent resolution, and a method of forming a resist pattern.

### Means for Solving the Problems

As a result of extensive and intensive studies, present inventors have found that the aforementioned problems can be solved by using a resin containing three specific structural units as a base resin. The present invention has been completed, based on this finding.

Specifically, a first aspect of the present invention is a positive resist composition including a resin component (A) which exhibits increased solubility in an alkali developing solution under action of acid, and an acid-generator component (B) which generates acid upon exposure,

wherein the resin component (A) includes a structural unit (a1) derived from hydroxystyrene, a structural unit (a2) represented by general formula (a2-1) or (a2-2) shown below, and a structural unit (a3) represented by general formula (a3-1) or (a3-2) shown below.

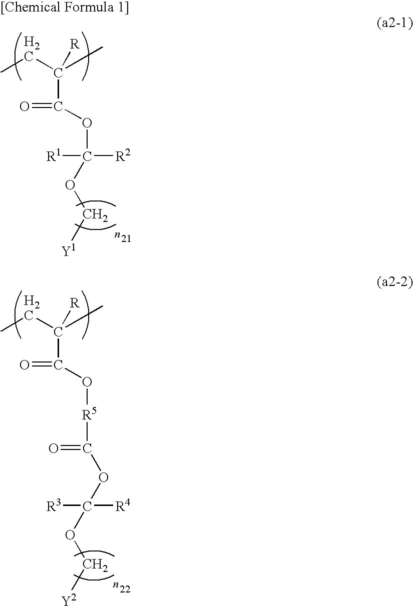

(In general formula (a2-1), R represents a hydrogen atom, a halogen atom, a lower alkyl group or a halogenated lower alkyl group; R¹ and R² each independently represents a hydrogen atom or a lower alkyl group; Y¹ represents a lower alkyl group or a monovalent aliphatic cyclic group; and n₂₁ represents an integer of 0 to 3. In general formula (a2-2), R represents a hydrogen atom, a halogen atom, a lower alkyl group or a halogenated lower alkyl group; R³ and R⁴ each independently represents a hydrogen atom or a lower alkyl group; R⁵ represents an alkylene group or a divalent aliphatic cyclic group; Y² represents a lower alkyl group or a monovalent aliphatic cyclic group; and n₂₂ represents an integer of 0 to 3.)

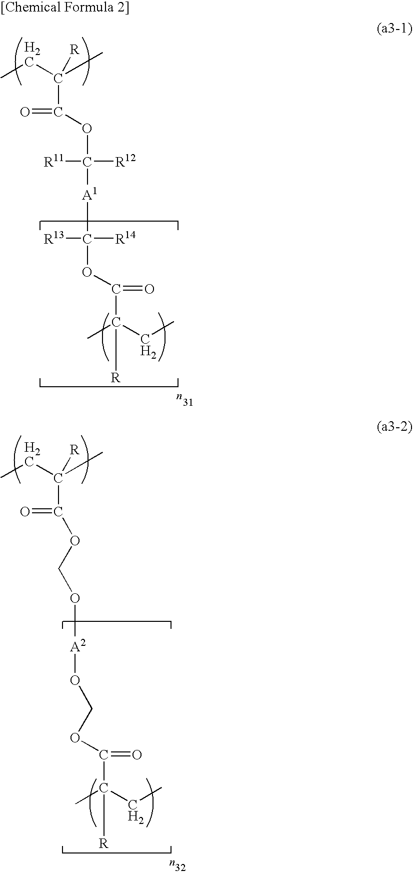

(In general formula (a3-1), R represents a hydrogen atom, a halogen atom, a lower alkyl group or a halogenated lower alkyl group and the plurality of R may be the same or different; R¹¹ to R¹⁴ each independently represents a lower alkyl group; A¹ represents an organic group having a valency of (n₃₁+1); and n₃₁ represents an integer of 1 to 4. In general formula (a3-2), R represents a hydrogen atom, a halogen atom, a lower alkyl group or a halogenated lower alkyl group and the plurality of R may be the same or different; A² represents an organic group having a valency of (n₃₂+1); and n₃₂ represents an integer of 1 to 4.)

A second aspect of the present invention is a method of forming a resist pattern, including: forming a resist film on a substrate using a positive resist composition of the first aspect; subjecting the resist film to exposure; and developing the resist film to form a resist pattern.

In the present description and claims, the term “structural unit” refers to a monomer unit that contributes to the formation of a resin (polymer).

An “alkyl group” includes linear, branched or cyclic, monovalent saturated hydrocarbon, unless otherwise specified.

An “alkylene group” includes linear, branched or cyclic, divalent saturated hydrocarbon, unless otherwise specified.

A “lower alkyl group” is an alkyl group of 1 to 5 carbon atoms.

The term “exposure” is used as a general concept that includes irradiation with any form of radiation.

### EFFECTS OF THE INVENTION

According to the present invention, there are provided a positive resist composition which is capable of forming a resist pattern with excellent resolution, and a method of forming a resist pattern.

### BEST MODE FOR CARRYING OUT THE INVENTION

### Positive Resist Composition

The positive resist composition of the present invention includes a resin component (A) (hereinafter, frequently referred to as “component (A)”) which exhibits increased solubility in an alkali developing solution under action of acid, and an acid-generator component (B) (hereinafter, frequently referred to as “component (B)”) which generates acid upon exposure.

The positive resist composition is alkali insoluble prior to exposure, and when acid is generated from the component (B) upon exposure, the generated acid acts on the component (A) to increase the alkali solubility thereof. Therefore, in the formation of a resist pattern, by conducting selective exposure of a resist film formed by applying the positive resist composition onto a substrate, the exposed portions become alkali soluble, whereas the unexposed portions remain alkali insoluble, and hence, a resist pattern can be formed by alkali developing.

### <Component (A)>

A component (A) includes a structural unit (a1) derived from hydroxystyrene, a structural unit (a2) represented by general formula (a2-1) or (a2-2) shown above, and a structural unit (a3) represented by general formula (a3-1) or (a3-2) shown above.

[Structural Unit (a1)]

A structural unit (a1) is a structural unit derived from hydroxystyrene. The effects of the present invention are obtained due to the inclusion of the structural unit (a1) as well as the structural units (a2) and (a3) described later in the component (A). Moreover, the inclusion of the structural unit (a1) in the component (A) improves dry etching resistance. Furthermore, there is also such an advantage that hydroxystyrene serving as a raw material of the structural unit (a1) is easily available at a low cost.

Here, the term “hydroxystyrene” refers to a general concept including: hydroxystyrene itself; structures in which the hydrogen atom at the α-position in hydroxystyrene has been substituted by another substituent group or atom such as a halogen atom, an alkyl group, or a halogenated alkyl group; and derivatives thereof. The term “structural unit derived from hydroxystyrene” refers to a structural unit which is formed by the cleavage of the ethylenic double bond of hydroxystyrene.

Examples of the structural unit (a1) include structural units represented by the following general formula (a-1).

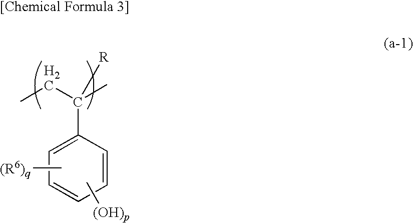

(wherein, R represents a hydrogen atom, a halogen atom, a lower alkyl group or a halogenated lower alkyl group; R⁶ represents a lower alkyl group; p represents an integer of 1 to 3; and q represents an integer of 0 to 2.)

Examples of the halogen atom for R in general formula (a-1) include a fluorine atom, a chlorine atom, a bromine atom and an iodine atom, and a fluorine atom is particularly desirable.

The lower alkyl group for R is an alkyl group of 1 to 5 carbon atoms and specific examples thereof include linear or branched alkyl groups such as a methyl group, an ethyl group, a propyl group, an isopropyl group, an n-butyl group, an isobutyl group, a tert-butyl group, a pentyl group, an isopentyl group, and a neopentyl group, Of these, a methyl group is preferable.

The halogenated lower alkyl group is a group in which a part or all of the hydrogen atoms of the aforementioned alkyl group is substituted with the aforementioned halogen atoms, and is preferably a fluorinated lower alkyl group, and still more preferably a lower alkyl group in which all hydrogen atoms of the all group have been substituted with fluorine atoms. Specific examples of the fluorinated lower alkyl group include a trifluoromethyl group, a hexafluoroethyl group, a heptafluoropropyl group, and a nonafluorobutyl group.

As R, a hydrogen atom or a lower alkyl group is preferable, and a hydrogen atom or a methyl group is particularly desirable.

p represents an integer of 1 to 3, and preferably 1.

The bonding position of the hydroxyl group may be any one of the opposition, the m-position, or the p-position of the phenyl group, but if p is 1, the p-position is preferred in terms of availability and low cost. If p is 2 or 3, any combination of the substitution positions is suitable.

q represents an integer of 0 to 2, preferably 0 or 1, and particularly preferably 0 from an industrial point of view.

As the lower alkyl group for R⁶, the same lower alkyl group as those for R can be used.

If q is 1, the substitution position of R⁶ may be any one of the o-position, the m-position, or the p-position, and if q is 2, any combination of the substitution positions is suitable.

As the structural unit (a1), one type of structural unit may be used alone, or two or more types of structural units may be used in combination.

The amount of the structural unit (a1) within the component (A) based on the combined total of all structural units constituting the component (A) is preferably 50 to 90 mol %, more preferably 55 to 85 mol %, and still more preferably 60 to 80 mol %. By making the amount of the structural unit (a1) within the above range, a suitable level of alkali solubility as well as a good balance with the other structural units can be achieved.

[Structural Unit (a2)]

The structural unit (a2) is a structural unit represented by general formula (a2-1) or (a2-2) above. Hereinafter, the structural unit represented by general formula (a2-1) will be referred to as the structural unit (a2-1), In addition, the structural unit represented by general formula (a2-2) will be referred hereinafter to as the structural unit (a2-2).

A group represented by formula —C(R¹)R²)—O—(CH₂)n₂₂-Y¹ in general formula (a2-1) and a group represented by formula —C(R³)(R⁴)—O—(CH₂)n₂₂-Y² in general formula (a2-2) are so-called acetal-type acid dissociable dissolution inhibiting groups.

Both of the structural units (a2-1) and (a2-2) have a common structure in which the aforementioned acetal-type acid dissociable dissolution inhibiting group is bonded to the oxygen atom at the terminal of the carbonyloxy group (—C(O)—O—). In such a structure, when acid is generated from the component (B) upon exposure, the action of the acid causes cleavage of the bond between the acid dissociable, dissolution inhibiting group and the oxygen atom at the terminal of the carbonyloxy group.

In the present description and claims, the phrase “acid dissociable” used in the term “acid dissociable, dissolution inhibiting group” means that the group is dissociable from the component (A) due to the action of acid generated from the component (B) upon exposure. On the other hand, the phrase “dissolution inhibiting group” used in the term “acid dissociable, dissolution inhibiting group” refers to a group having a alkali dissolution-inhibiting effect that renders the entire component (A) alkali insoluble prior to dissociation, and then following dissociation, renders the entire component (A) alkali soluble.

Therefore, the component (A) that includes the structural unit (a2) is alkali insoluble prior to exposure, and when acid is generated from the component (B) upon exposure, the acid dissociable dissolution inhibiting group is dissociated by the generated acid, thereby increasing the alkali solubility of the entire component (A) to render it alkali soluble. Therefore, in the formation of a resist pattern, by conducting selective exposure of a resist film formed by applying the positive resist composition onto a substrate, the exposed portions become alkali soluble, whereas the unexposed portions remain alkali insoluble, and hence, a resist pattern can be formed by alkali developing.

As R in general formula (a2-1), the same as R in general formula (a-1) above can be used.

R¹ and R² each independently represents a hydrogen atom or a lower alkyl group. The lower alkyl group for R¹ and R² is an alkyl group of 1 to 5 carbon atoms and specific examples thereof include linear or branched alkyl groups such as a methyl group, an ethyl group, a propyl group, an isopropyl group, an n-butyl group, an isobutyl group, a tert-butyl group, a pentyl group, an isopentyl group, and a neopentyl group. Of these, a methyl group or an ethyl group is preferable in view of industrial availability.

In terms of achieving superior effects for the present invention, at least one of R¹ and R² is preferably a hydrogen atom, and those cases in which both groups are hydrogen atoms are particularly preferred.

n₂₁ represents an integer of 0 to 3, preferably 0 or 1, and most preferably 1.

Y¹ represents a lower alkyl group or a monovalent aliphatic cyclic group.

As the lower alkyl group for Y¹, the same lower alkyl groups as those for R above can be used.

As the aliphatic cyclic group for Y¹, any of the aliphatic monocyclic or polycyclic groups which have been proposed for conventional ArF resists and the like can be appropriately selected for use.

In the present description and claims, the term “aliphatic cyclic group” refers to a monocyclic group or a polycyclic group that has no aromaticity.

The aliphatic cyclic groups within Y¹ may or may not have a substituent. Examples of substituents include a lower alkyl group of 1 to 5 carbon atoms, a fluorine atom, a fluorinated lower alkyl group of 1 to 5 carbon atoms, and a hydrophilic group. The fluorinated lower alkyl group is a group in which some or all of the hydrogen atoms of the aforementioned “lower alkyl group of 1 to 5 carbon atoms” are substituted with fluorine atoms. Examples of the hydrophilic group include ═O, —COOR (wherein R is an alkyl group), alcoholic hydroxyl groups, —OR (wherein R is an alkyl group), imino groups, and amino groups, although from the viewpoint of availability, an ═O group or an alcoholic hydroxyl group is preferred.

The basic ring structure (the base ring) of the aliphatic cyclic group excluding substituent groups may be either a ring formed solely from carbon and hydrogen (a hydrocarbon ring), or a heterocycle in which a portion of the carbon atoms that constitute a hydrocarbon ring are substituted with a hetero atom such as a sulfur atom, an oxygen atom, or a nitrogen atom. In terms of the effects achieved for the present invention, the base ring within the group Y¹ is preferably a hydrocarbon ring.

This hydrocarbon ring can be appropriately selected from the multitude of compounds proposed for use within KrF resists, ArF resists and the like, and examples include monocycloalkanes, and polycycloalkanes such as bicycloalkanes, tricycloalkanes, and tetracycloalkanes. Specific examples of monocycloalkanes include cyclopentane and cyclohexane. Specific examples of polycycloalkanes include adamantane, norbornane, norbornene, methylnorbornane, ethylnorbomane, methylnorbornene, ethylnorbornene, isobornane, tricyclodecane, and tetracyclododecane. Of these, cyclohexane, cyclopentane, adamantane, norbornane, norbornene, methylnorbornane, ethylnorbornane, methylnorbornene, ethylnorbornene, and tetracyclododecane are preferred industrially, and adamantane is particularly desirable.

Examples of the group represented by formula —C(R¹)(R²)—O—(CH₂)n₂₁-Y¹ include the groups represented by formulas (4) through (15) shown below.

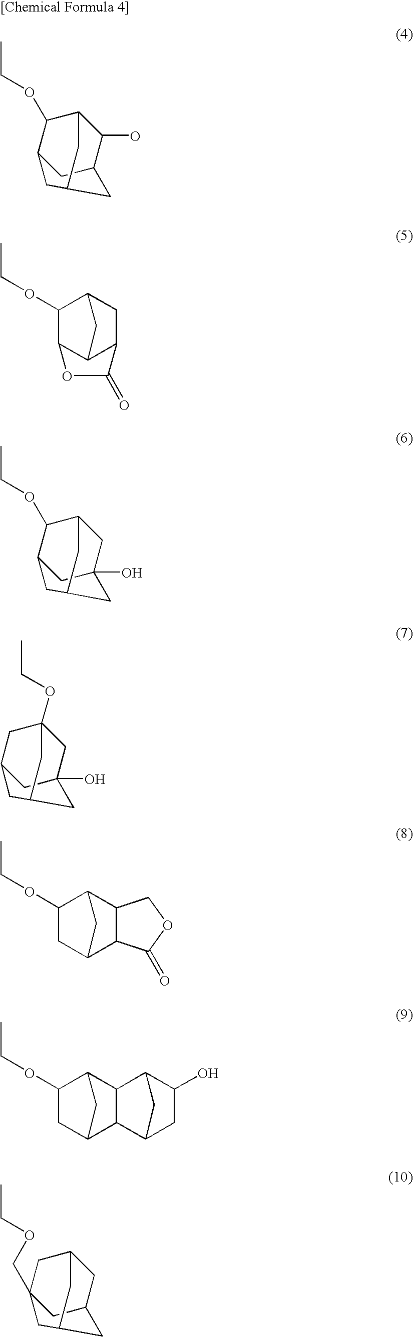

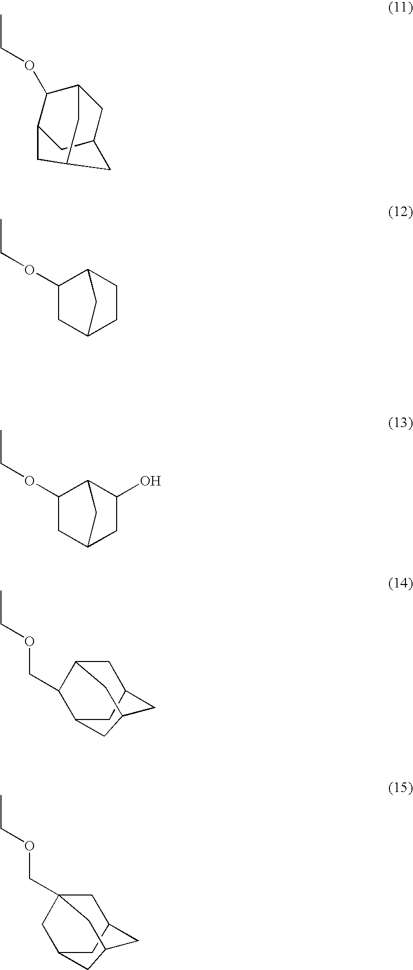

As R in general formula (a2-2), the same as R in general formula (a2-1) can be used.

As R³ and R⁴ in general formula (a2-2), the same as those defined above for R¹ and R² in formula (a2-1), respectively, can be used.

As n₂₂ in general formula (a2-2), the same as those defined above for n₂₁ in general formula (a2-1) can be used.

As Y² in general formula (a2-2), the same as those defined for Y¹ in general formula (a2-1) can be used.

R⁵ represents an alkylene group or a divalent aliphatic cyclic group.

As the alkylene group for R⁵, an alkylene group of 1 to 4 carbon atoms is preferable.

The aliphatic cyclic group for R⁵ may or may not have a substituent. Examples of substituents include a lower alkyl group of 1 to 5 carbon atoms, a fluorine atom, a fluorinated lower alkyl group of 1 to 5 carbon atoms, and an oxygen atom (═O).

The basic ring of the aliphatic cyclic group for R⁵ exclusive of substituents is not limited to being constituted from only carbon and hydrogen (not limited to hydrocarbon groups), but is preferably a hydrocarbon group. Further, the “hydrocarbon group” may be either saturated or unsaturated, but is preferably saturated. Furthermore, the aliphatic cyclic group for R⁵ is preferably a polycyclic group.

As such aliphatic cyclic groups for R⁵, groups in which two or more hydrogen atoms have been removed from a monocycloalkane or a polycycloalkane such as a bicycloalkane, tricycloalkane or tetracycloalkane which may or may not be substituted with a lower alkyl group, a fluorine atom or a fluorinated lower alkyl group, may be used. Specific examples include groups in which two or more hydrogen atoms have been removed from a monocycloalkane such as cyclopentane and cyclohexane; and groups in which two or more hydrogen atoms have been removed from a polycycloalkane such as adamantane, norbornane, isobornane, tricyclodecane or tetracyclododecane.

As the aliphatic cyclic group for Y², a group represented by general formula (y-1) shown below is particularly desirable.

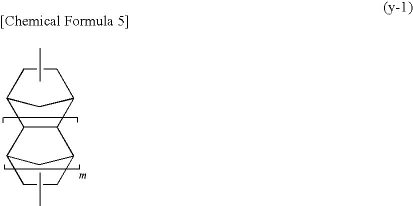

(wherein, m represents 0 or 1, and preferably 1.)

Specific examples of the structural unit represented by general formula (a2-1) (hereinafter, referred to as the structural unit (a2-1)) include structural units represented by general formulas (a1-2-1) to (a1-2-43) shown below.

Specific examples of the structural unit represented by general formula (a2-2) (hereinafter, referred to as the structural unit (a2-2)) include structural units represented by general formulas (a1-4-1) to (a1-4-30) shown below.

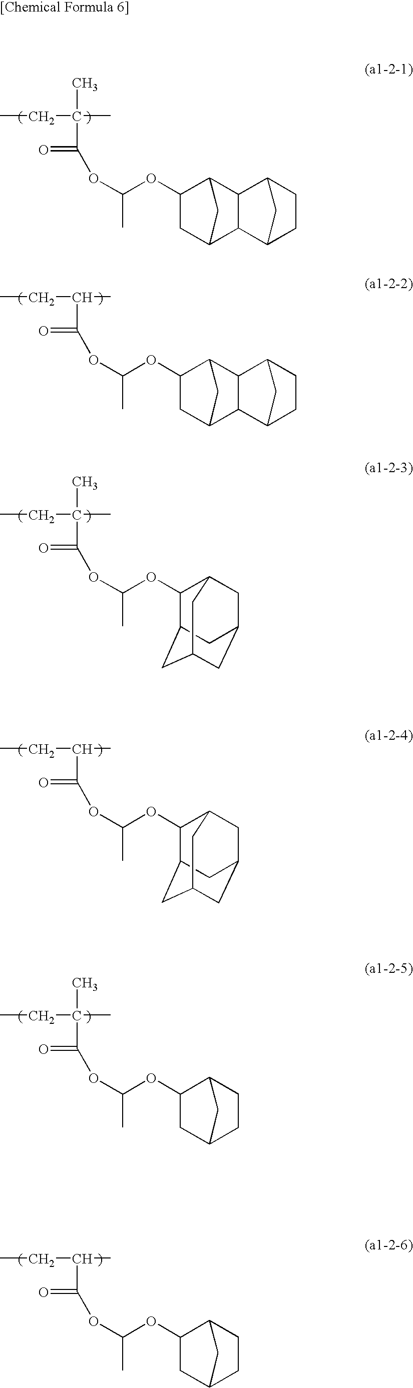

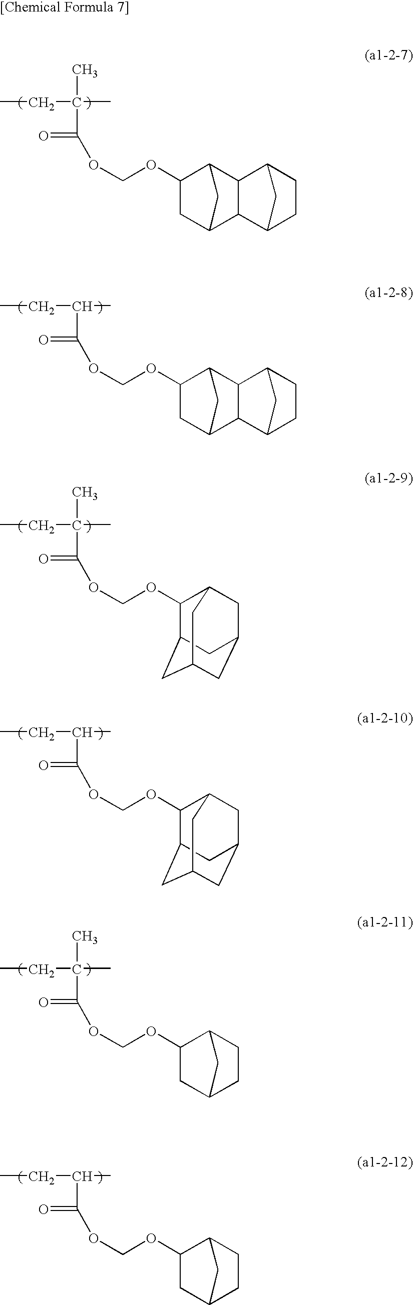

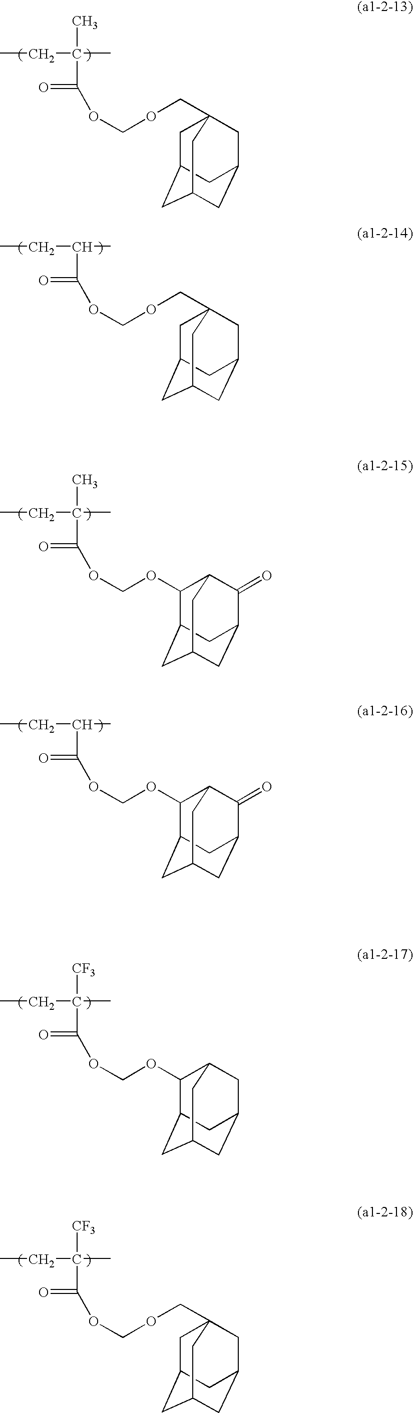

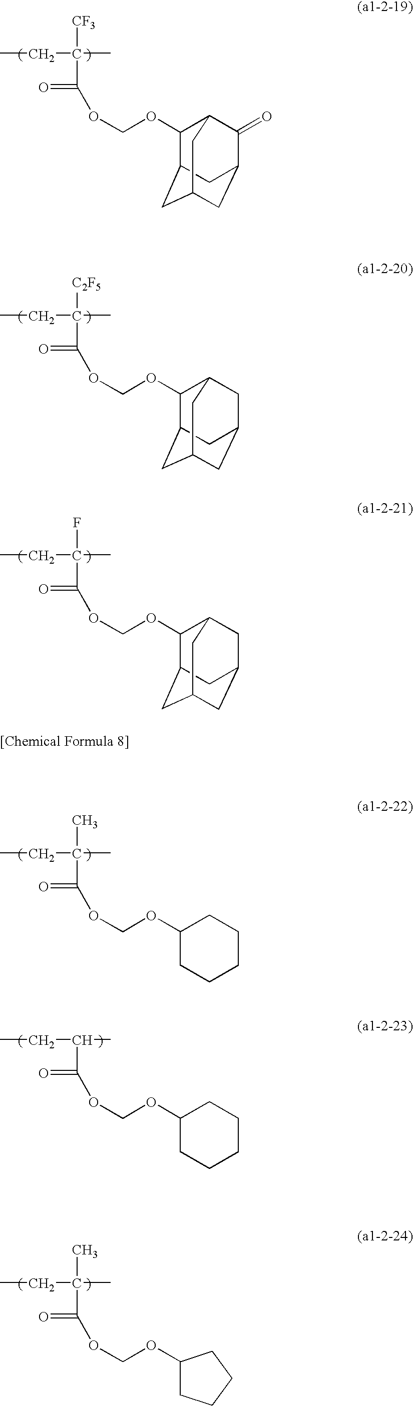

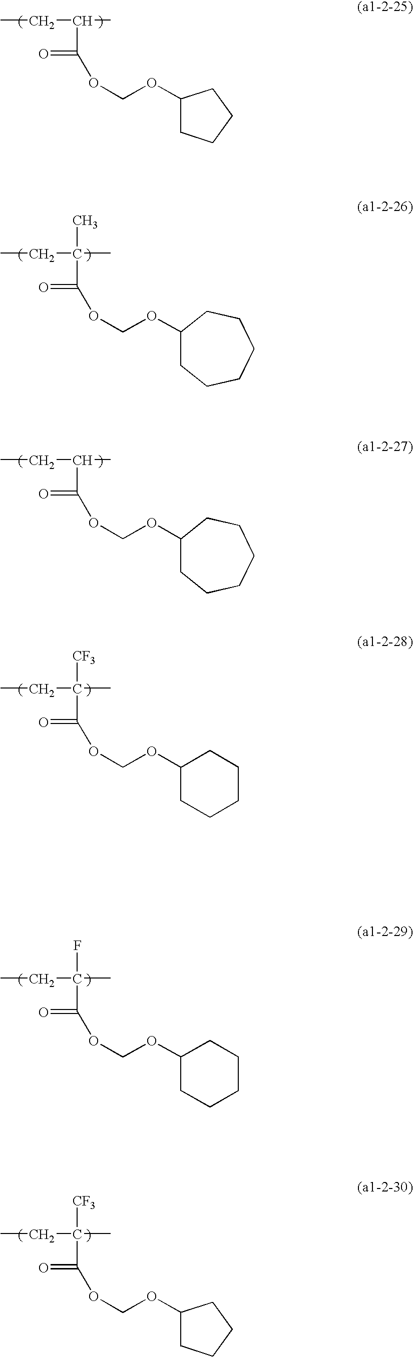

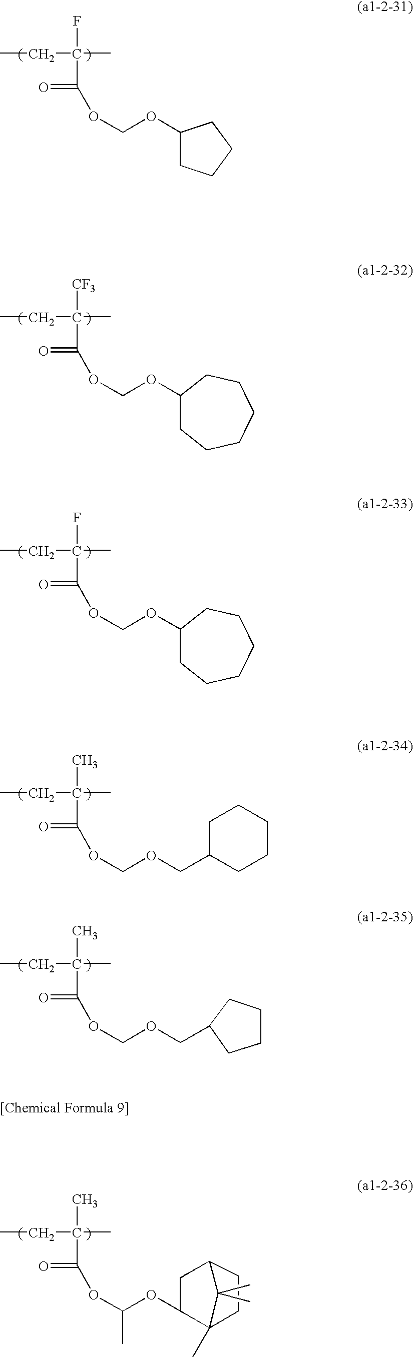

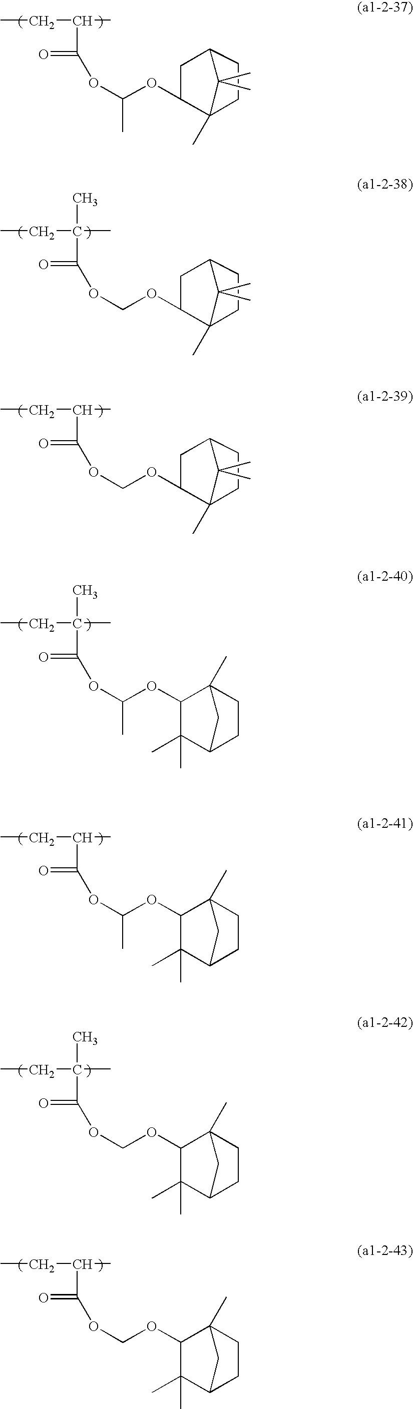

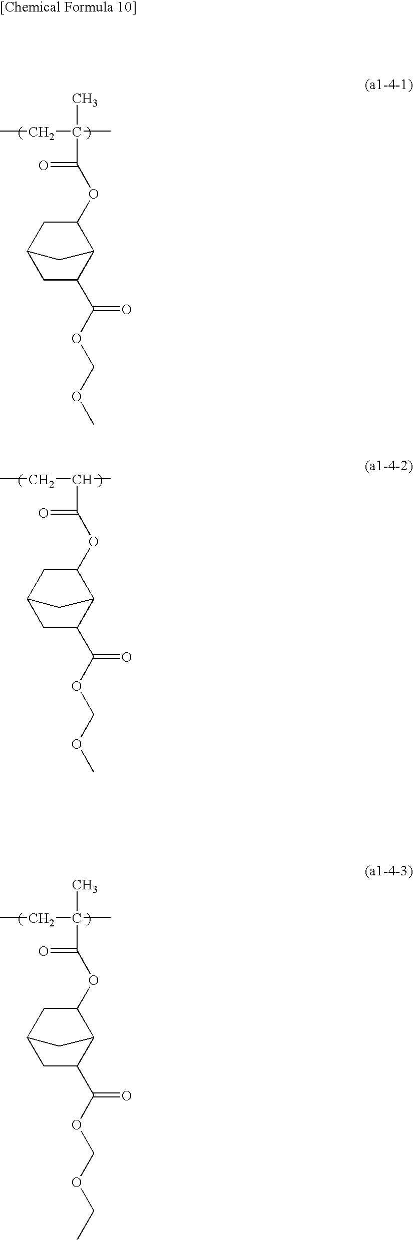

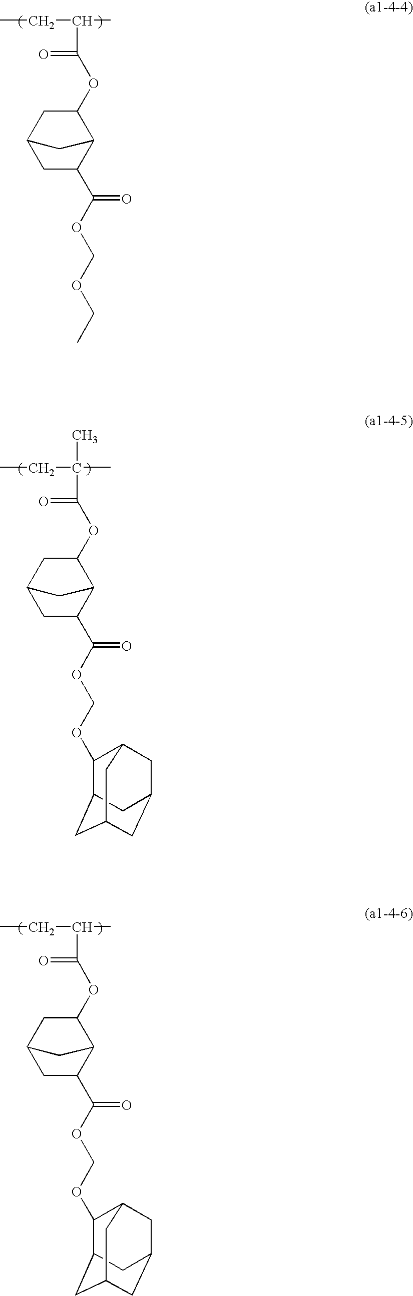

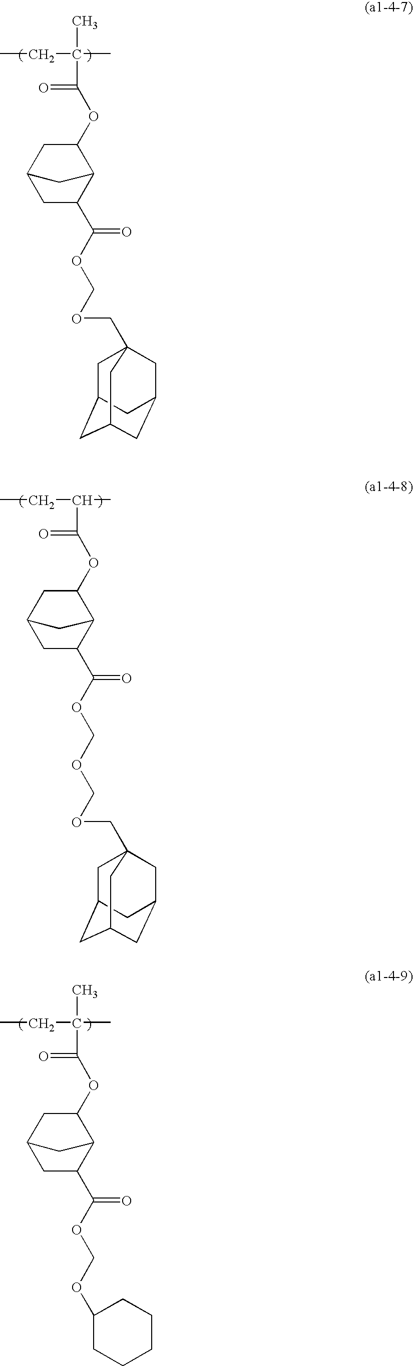

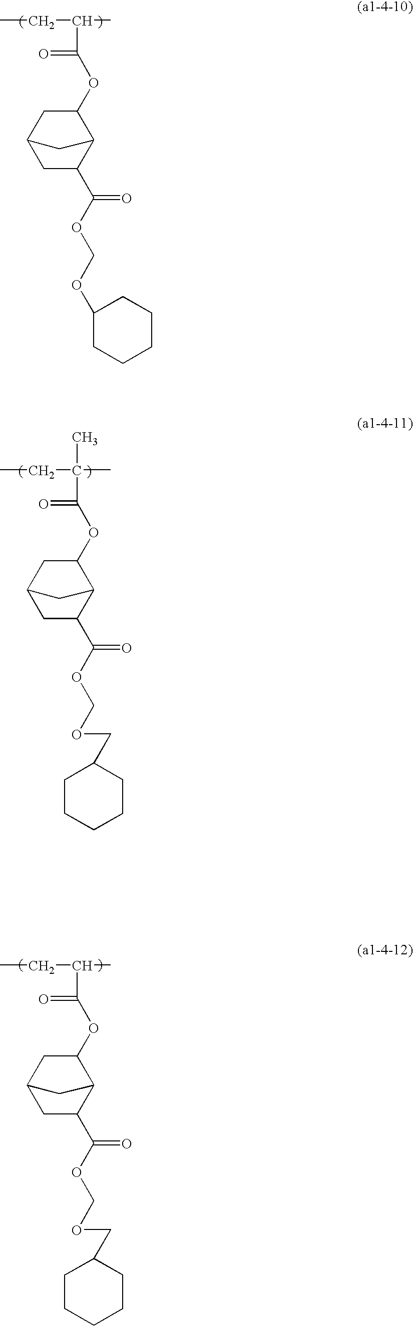

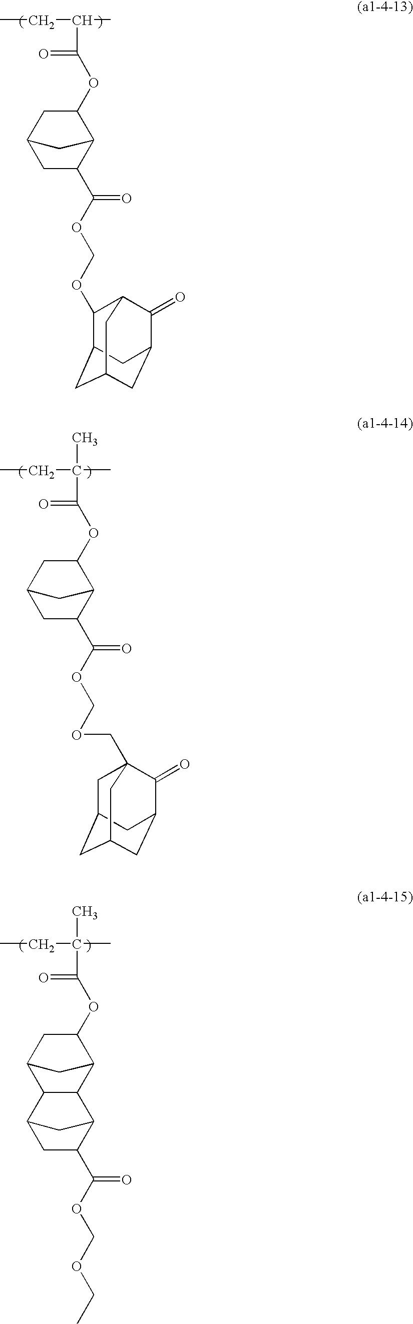

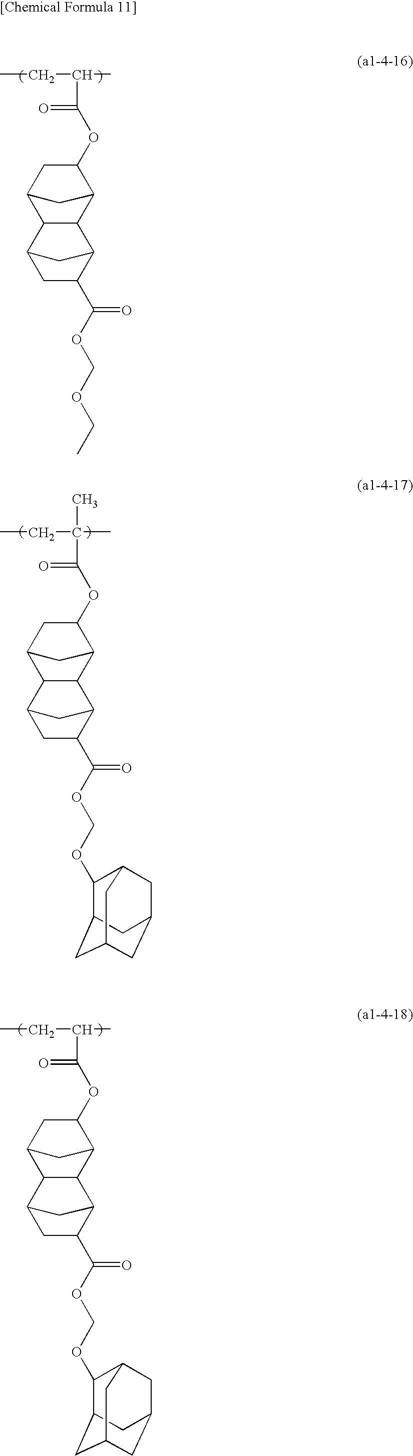

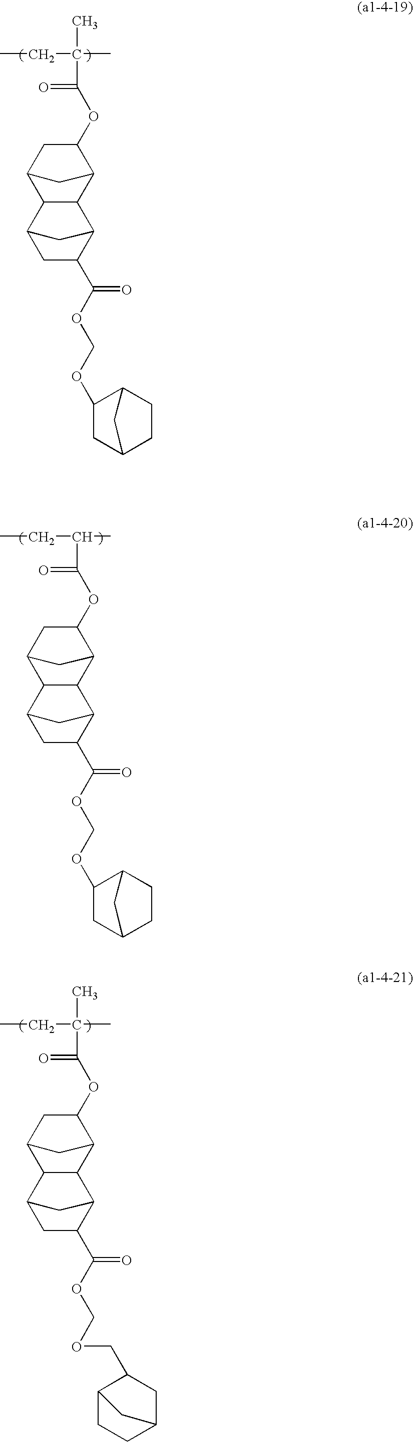

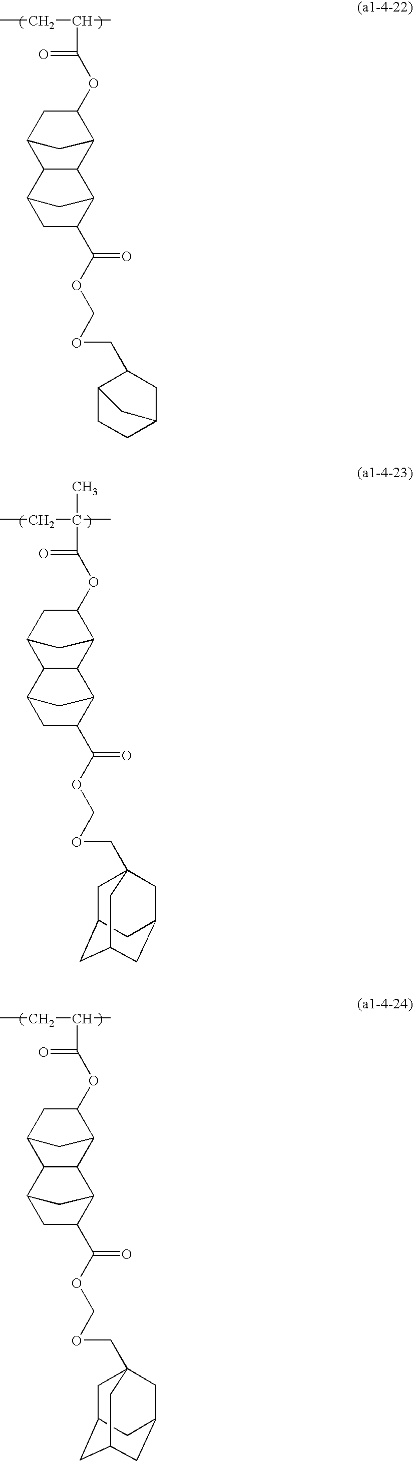

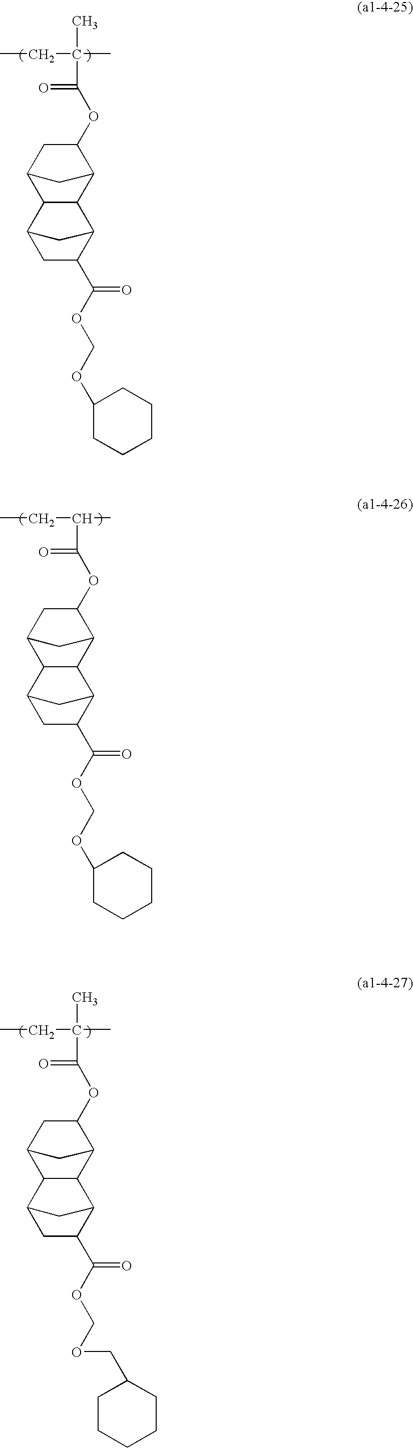

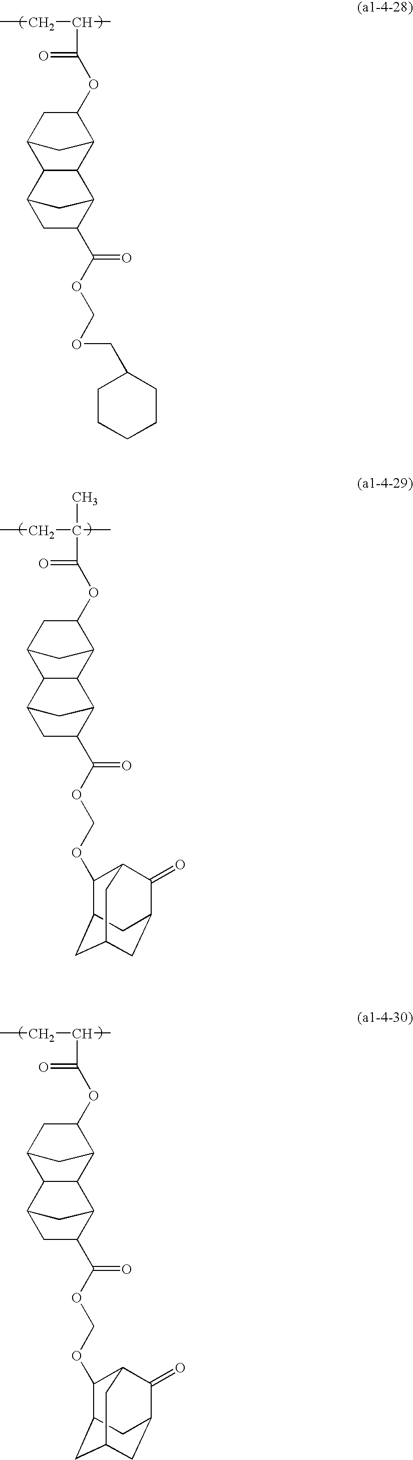

In terms of achieving superior effects for the present invention, it is particularly desirable that the structural unit (a2) be the structural unit (a2-1). Of these, in terms of achieving superior effects for the present invention, the structural units represented by formulas (a1-2-9), (a1-2-10), (a1-2-13), (a1-2-14), (a1-2-15), and (a1-2-16) are preferable.

As the structural unit (a2), one type of structural unit may be used alone, or two or more types may be used in combination.

In the component (A), the amount of the structural unit (a2) based on the combined total of all structural units constituting the component (A) is preferably 5 to 50 mol %, more preferably 10 to 40 mol %, and still more preferably 15 to 35 mol %. By making the amount of the structural unit (a2) at least as large as 5 mol %, a pattern can be easily formed using a positive resist composition prepared from the component (A). On the other hand, by making the amount of the structural unit (a2) no more than 50 mol %, a good balance can be achieved with the other structural units.

[Structural Unit (a3)]

The structural unit (a3) is a structural unit represented by general formula (a3-1) or (a3-2) above. Hereinafter, the structural unit represented by general formula (a3-1) will be referred to as the structural unit (a3-1). In addition, the structural unit represented by general formula (a3-2) will hereinafter be referred to as the structural unit (a3-2).

The structural unit (a3-1) includes one —CO—O—C(R¹¹)(R¹²)-A¹- residue and n₃₁ (that is, one or more) —CO—O—C(R¹³)(R¹⁴)- residues bonded to A¹ in the structure thereof. In such structures, when acid is generated from the component (B), the action of the acid causes cleavage of the bonds between the oxygen atoms at the terminal of the carbonyloxy groups and the tertiary carbon atoms that are bonded to the oxygen atoms (that is, the carbon atom to which R¹¹ and R¹² are bonded and the carbon atom to which R¹³ and R¹⁴ are bonded).

The structural unit (a3-2) includes one —CO—O—CH₂—O-A²- residue and n₃₂ (that is, one or more) —CO—O—CH₂—O— residues bonded to A² in the structure thereof. In such structures, when acid is generated from the component (B), the action of the acid causes cleavage of the bonds between the oxygen atoms at the terminal of the carbonyloxy groups and the carbon atoms that are bonded to the oxygen atoms (that is, the carbon atoms of methylene groups).

In other words, the structural unit (a3) is dissociated under action of acid generated from the component (B).

[Structural Unit (a3-1)]

As R in general formula (a3-1), the same as R in general formula (a-1) above can be used. The plurality of R in general formula (a-1) may be the same or different.

R¹¹ to R¹⁴ each independently represents a lower alkyl group and examples of the lower alkyl group include the same lower alkyl groups as those for R. The lower alkyl group for R¹¹ to R¹⁴ is preferably an alkyl group of 1 to 4 carbon atoms and specific examples thereof include a methyl group, an ethyl group, an n-propyl group, an isopropyl group, an n-butyl group, and a t-butyl group. Of these, a methyl group is preferable.

n₃₁ is an integer of 1 to 4, preferably 1 or 2, and most preferably 1.

A¹ represents an organic group having a valency of (n₃₁+1). For example, A¹ represents a divalent organic group when n₃₁ is 1, and represents a trivalent organic group when n₃₁ is 2.

In the structural unit (a3-1), as the valency of the group A¹ increases, the number of group residues bonded to A¹ also increases, forming a structure with a more dense radial structure. For example, when A¹ represents a divalent organic group, the structural unit (a3-1) adopts a structure in which two groups are bonded to A¹. When A¹ represents a trivalent organic group, the structural unit (a3-1) adopts a structure in which ee groups are bonded to A¹.

In the present description and claims, the term “organic group” refers to a group which is constituted of a carbon atom and at least one atom other than a carbon atom. Examples of the “atom other than a carbon atom” which constitutes the organic group include a hydrogen atom, a halogen atom (such as a fluorine atom, a chlorine atom, a bromine atom and an iodine atom), an oxygen atom, a nitrogen atom, and a sulfur atom.

Basically, as the organic group, a group containing carbon and hydrogen as the main component elements is preferable. Examples of such groups include a hydrocarbon group constituted of only carbon atoms and hydrogen atoms; a hydrocarbon group in which some or all of the hydrogen atoms thereof are substituted with substituents; and a hydrocarbon group in which some of the carbon atoms are substituted with an atom or group other than a carbon atom or hydrogen atom.

As a substituent, there is no particular limitation as long as it is an atom or group other than a carbon atom or hydrogen atom, and examples thereof include an oxygen atom (═O), a halogen atom (such as a fluorine atom, a chlorine atom, a bromine atom and an iodine atom), a carboxyl group, a hydroxyl group or a cyano group.

Examples of an atom or group other t a carbon atom or hydrogen atom, with which some of the carbon atoms of a hydrocarbon group may be substituted include —O—, —NH—, and —N═.

This hydrocarbon group may be a straight-chain, branched or cyclic group, or may also be a combination thereof. Furthermore, either a saturated hydrocarbon group that contains no unsaturated bonds, or an unsaturated hydrocarbon group that includes an unsaturated bond is suitable.

As the hydrocarbon group, a hydrocarbon group of 1 to 20 carbon atoms is preferable, and a straight-chain saturated hydrocarbon group of 1 to 5 carbon atoms or a hydrocarbon group containing a cyclic group of 4 to 15 carbon atoms is more preferable in terms of achieving superior effects for the present invention.

A straight-chain saturated hydrocarbon group of 1 to 5 carbon atoms is preferable in consideration of industrial availability, and the number of carbon atoms in the saturated hydrocarbon group is preferably 1 to 3 and more preferably 2 or 3. For example, when n₃₁ is 1, the saturated hydrocarbon group is an alkylene group and examples thereof include a methylene group, an ethylene group, an n-propylene group and an n-butylene group.

Furthermore, from the viewpoint of etching resistance, a hydrocarbon group containing a cyclic group of 4 to 15 carbon atoms is preferred. Here, the description “hydrocarbon group containing a cyclic group of 4 to 15 carbon atoms” refers to a hydrocarbon group that includes a cyclic group (a cyclic hydrocarbon group) of 4 to 15 carbon atoms within the structure of the group, and this group may be composed solely of the cyclic hydrocarbon group of 4 to 15 carbon atoms, or may be a group in which a straight-chain hydrocarbon group such as a methylene group or ethylene group is bonded to the cyclic hydrocarbon group. The number of carbon atoms within the cyclic group is even more preferably within a range from 4 to 10, and is most preferably from 4 to 8.

Furthermore, the number of carbon atoms within the hydrocarbon group containing the cyclic group of 4 to 15 carbon atoms is preferably within a range from 4 to 20, and even more preferably from 4 to 10.

The cyclic group of 4 to 15 carbon atoms may be either an aliphatic cyclic group or an aromatic cyclic group. Furthermore, the group may be either a monocyclic group or a polycyclic group. Of these, from the viewpoint of etching resistance, the cyclic group of 4 to 15 carbon atoms is preferably an aliphatic cyclic group.

These types of aliphatic cyclic groups of 4 to 15 carbon atoms can be selected appropriately from the multitude of groups proposed for use with ArF resists. Specific examples of aliphatic cyclic groups of 4 to 15 carbon atoms include groups in which two or more hydrogen atoms have been removed from a cycloalkane, bicycloalkane, bicycloalkene, tricycloalkane, tetracycloalkane, methylbicycloalkane, methylbicycloalkene, methyltricycloalkane, methyltetracycloalkane, ethylbicycloalkane, ethylbicycloalkene, ethyltricycloalkane, ethyltetracycloalkane or the like. Particular examples include groups in which two or more hydrogen atoms have been removed from cyclohexane, cyclopentane, or a polycycloalkane such as adamantane, norbornane, norbornene, methylnorbornane, ethylnorbornane, methylnorbornene, ethylnorbornene, isobornane, tricyclodecane or tetracyclododecane. Of the various possibilities, groups in which two or more hydrogen atoms have been removed from a cyclic saturated hydrocarbon group such as cyclohexane, cyclopentane, adamantane or norbornane (namely, cyclic saturated hydrocarbon groups) are preferred in terms of the resulting resolution, and the group in which two hydrogen atoms have been removed from cyclohexane is most desirable.

Furthermore, examples of aromatic cyclic groups of 4 to 15 carbon atoms include groups in which two or more hydrogen atoms have been removed from naphthalene, anthracene, phenanthrene or the like.

As the “hydrocarbon group in which some or all of the hydrogen atoms thereof are substituted with substituents”, an ether group having one C—O—C structure, a polyether group having two or more C—O—C structures, and an ester group having a CO—O—C structure may be used.

As the “hydrocarbon group in which some of the carbon atoms are substituted with an atom or group other than a carbon atom or hydrogen atom”, a heterocyclic group in which a portion of the carbon atoms that constitute the cyclic hydrocarbon group have been substituted with a hetero atom such as a nitrogen atom or oxygen atom may be used.

Specific examples of the organic groups for A¹ are shown below.

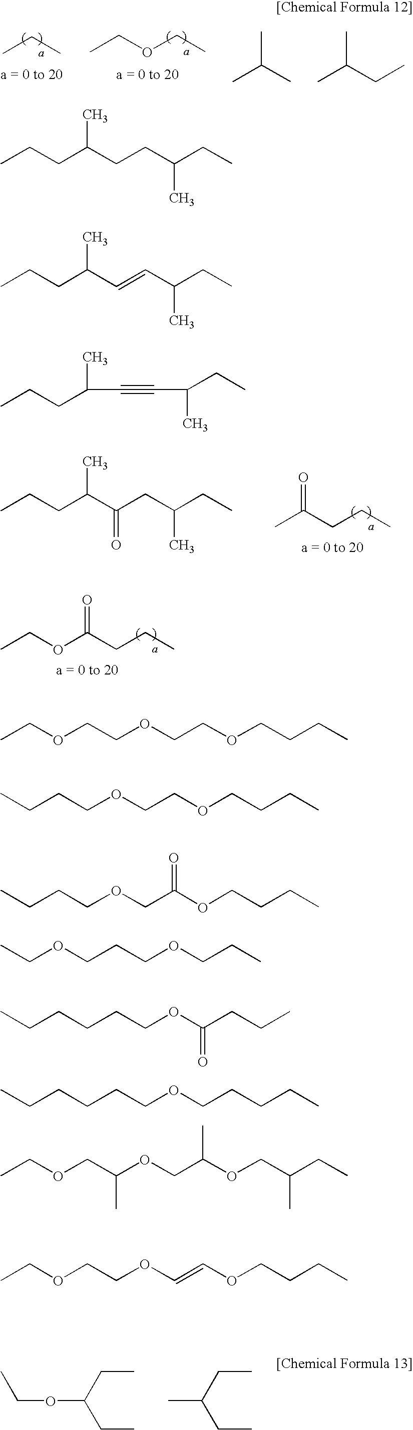

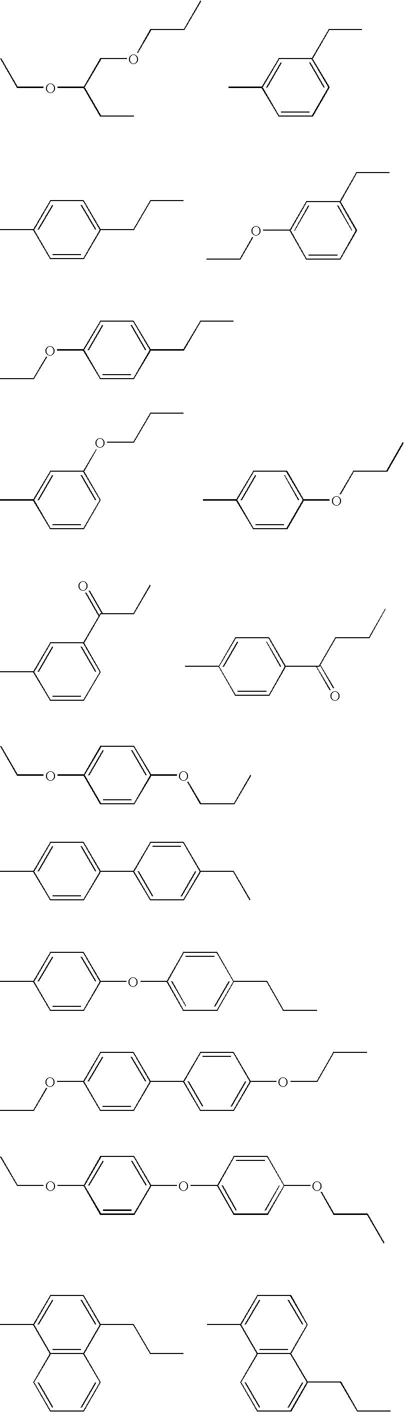

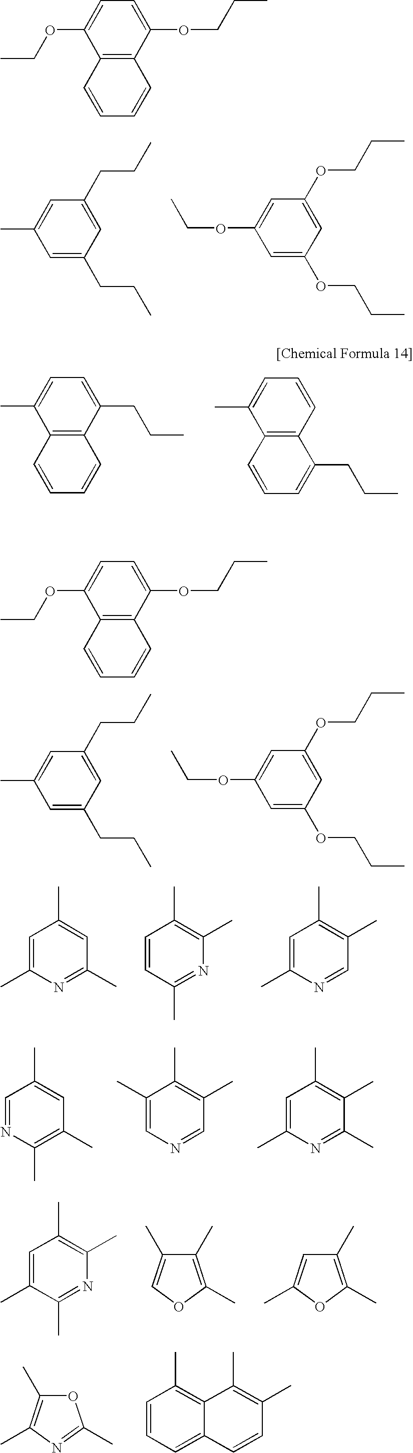

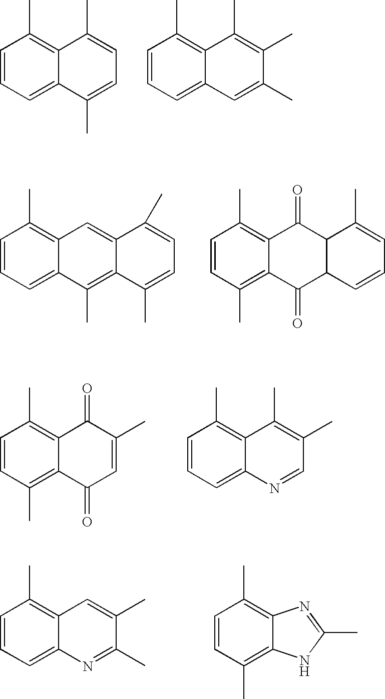

Of these, A¹ is particularly preferably an alkylene group of 2 to 5 carbon atoms. In other words, as the structural unit (a3-1), a structural unit represented by general formula (a3-1-1) shown below is desirable.

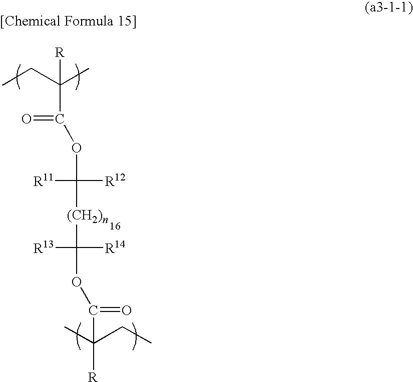

As R in general formula (a3-1-1), the same as R in general formula (a3-1) above can be used. In general formula (a3-1-1), R¹¹ to R¹⁴ are respectively as defined for R¹¹ to R¹⁴ in general formula (a3-1) above.

n₁₆ is an integer of 2 to 5, preferably 2 or 3, and most preferably 2.

The structural unit (a3-1) is derived from a compound represented by general formula (a3-1′) shown below (hereinafter referred to as the compound (a3-1′)); that is, a compound having a structure in which one CH₂═C(R)—CO—O—C(R¹¹)(R¹²)- residue and n₃₁ (that is, one or more) CH₂═C(R)—CO—O—C(R¹³)(R¹⁴)- residues are bonded to A¹.

Here, the structural unit “derived from the compound (a3-1′)” refers to a structural unit which is formed by the cleavage of the ethylenic double bond of the compound (a3-1′).

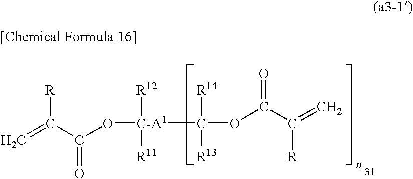

(wherein, R, R¹¹ to R¹⁴, A¹, and n₃₁ are respectively as defined for R, R¹¹ to R¹⁴, A¹, and n₃₁ in general formula (a3-1) above.)
[Structural Unit (a3-2)]

As R in general formula (a3-2), the same as R in general formula (a-1) above can be used. The plurality of R in general formula (a3-2) may be the same or different.

n₃₂ is an integer of 1 to 4, preferably 1 to 3, more preferably 1 or 2, and most preferably 1.

A² represents an organic group having a valency of (n₃₂+1) and examples of the organic group include the same groups as those described above for A¹.

In terms of achieving superior effects for the present invention, it is particularly preferable that A² be a hydrocarbon group of 1 to 20 carbon atoms.

As the hydrocarbon group of 1 to 20 carbon atoms, a straight-chain saturated hydrocarbon group of 1 to 5 carbon atoms or a hydrocarbon group containing a cyclic group of 4 to 15 carbon atoms is preferable as described above. The number of carbon atoms within the straight-chain saturated hydrocarbon group is even more preferably within a range from 1 to 4, and is most preferably from 1 to 3.

As the structural unit (a3-2), a structural unit represented by general formula (a3-2-1) or (a3-2-2) shown below is particularly desirable.

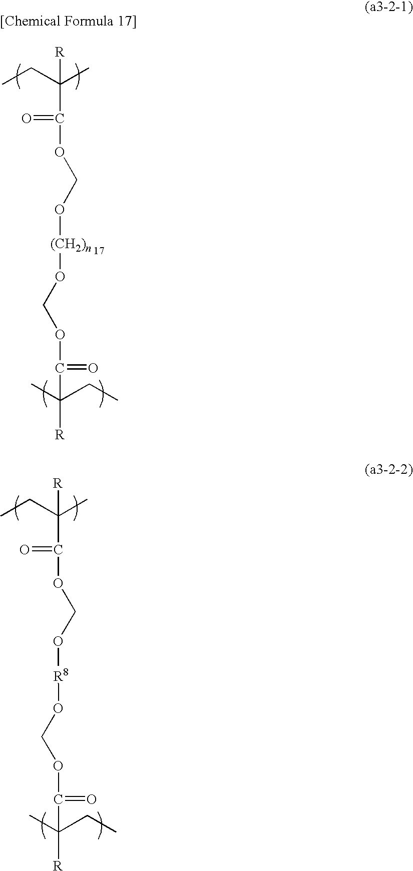

(wherein, R is as defined for R in general formula (a3-2) above; n₁₇ represents an integer of 1 to 3; and R⁸ represents a cyclic saturated hydrocarbon group of 4 to 15 carbon atoms.)

In general formula shown above, n₁₇ is preferably 2 or 3, and most preferably 2.

R⁸ is preferably a cyclic saturated hydrocarbon group of 4 to 8 carbon atoms; more preferably a group in which two hydrogen atoms have been removed from cyclohexane; and most preferably a group represented by general formula (1′) shown below,

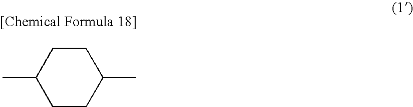

The structural unit (a3-2) is derived from a compound represented by general formula (a3-2′) shown below (hereafter referred to as the compound (a3-2′)); that is, a compound having a structure in which a plurality (that is, n₃₂+1) of CH₂═C(R)—CO—O—CH₂—O— residues are bonded to A².

Here, the structural unit “derived from the compound (a3-2′)” refers to a structural unit which is formed by the cleavage of the ethylenic double bond of the compound (a3-2′).

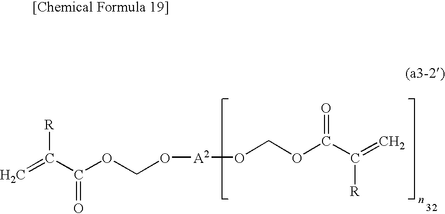

(wherein, R, A² and n₃₂ are respectively as defined for R, A² and n₃₂ in general formula (a3-2) above.)

The compound (a3-2′) can be synthesized using known methods, for example, by synthesizing a halogenated methyl ether compound represented by general formula (2′) shown below, and then reacting this halogenated methyl ether compound with (meth)acrylic acid. In the present description and claims, the term “(meth)acrylic acid” is a generic term that includes either or both of acrylic acid having a hydrogen atom bonded to the α-position and methacrylic acid having a methyl group bonded to the α-position.

Z-CH₂—O-A²-[O—CH₂-Z]n₃₂ (2′)

(wherein, A² and n₃₂ are respectively as defined for A² and n₃₂ in general formula (a3-2) above, and Z represents a halogen atom (such as a chlorine atom and a bromine atom)).

The above halogenated methyl ether compound can be obtained, for example, by adding paraformaldehyde to an alcohol compound represented by HO-A²-[OH]n₃₂ (wherein A² and n₃₂ are respectively as defined for A² and n₃₂ in general formula (a3-2) above) and blowing a 2.0 to 3.0 equivalence of halogenated hydrogen gas through the alcohol compound to conduct a reaction at 40 to 100° C. in the presence of hydrochloric acid.

As the structural unit (a3), one type of structural unit may be used alone, or two or more types of structural units may be used in combination.

In terms of achieving superior effects for the present invention, the structural unit (a3) is preferably the structural unit (a3-1) more preferably a structural unit in which A¹ within the structural unit (a3-1) is a hydrocarbon group of 1 to 20 carbon atoms, and still more preferably a structural unit represented by general formula (3-1-1).

In the component (A), the amount of the structural unit (a3) based on the combined total of all structural units constituting the component (A) is preferably 1 to 10 mol %, more preferably 2 to 8 mol %, and still more preferably 3 to 7 mol %. By making the amount of the structural unit (a3) at least as large as 1 mol %, the effects of the present invention are enhanced. On the other hand, by making the amount of the structural unit (a3) no more than 10 mol %, a good balance can be achieved with the other structural Wits and the solubility of the component (A) in an organic solvent is also improved.

### [Other Structural Units]

The component (A) may further include a structural unit (a4) derived from styrene, in addition to the structural units (a1), (a), and (a3).

In the present invention, the structural unit (a4) is not essential. However, when this structural unit is included, solubility of the component (A) in a developing solution can be adjusted. In addition, the inclusion of the structural unit (a4) in the component (A) improves dry etching resistance.

Here, the term “styrene” refers to a general concept including styrene itself, and structures in which the hydrogen atom at the α-position in styrene has been substituted by another substituent group or atom such as a halogen atom, an alkyl group, or a halogenated alkyl group. The term “structural unit derived from styrene” refers to a structural unit which is formed by the cleavage of the ethylenic double bond of styrene. In the styrene, the hydrogen atom of the phenyl group may be substituted by a substituent such as an alkyl group of 1 to 5 carbon atoms.

Examples of the structural unit (a4) include structural units represented by the following general formula (a4-1).

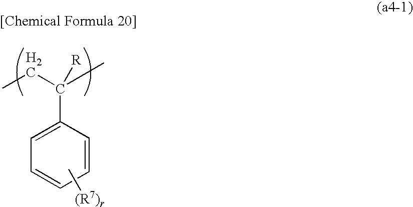

(wherein, R represents a hydrogen atom, a halogen atom, a lower alkyl group or a halogenated lower alkyl group; R⁷ represents a lower alkyl group; and r represents an integer of 0 to 3.)

In general formula (a4-1), R and R⁷ are respectively as defined for R and R⁶ in general formula (a-1) above.

r represents an integer of 0 to 3, preferably 0 or 1, and particularly preferably 0 from an industrial point of view.

If r is 1 to 3, the substitution position of R⁷ may be any one of the o-position, the m-position, or the p-position of the phenyl group, and if r is 2 or 3, any combination of the substitution positions is suitable.

As the structural unit (a4), one type of structural unit may be used alone, or two or more types of structural units may be used in combination.

When the component (A) contains the structural unit (a4), the amount of the structural unit (a4) in the component (A) based on the combined total of all structural units constituting the component (A) is preferably 1 to 20 mol %, more preferably 3 to 15 mol %, and still more preferably 5 to 15 mol %. By making the amount of the structural unit (a4) at least as large as 1 mol %, the effects of the present invention due to the presence of the structural unit (a4) are enhanced. On the other hand, by making the amount of the structural unit (a4) no more than 20 mol %, a good balance can be achieved with the other structural units.

The component (A) may also have a structural unit (a5) which is other than the above-mentioned structural units (a1) to (a4), as long as the effects of the present invention are not impaired.

As the structural unit (a5), any other structural unit which cannot be classified as one of the above structural units (a1) to (a4) can be used without any particular limitations, and any of the multitude of conventional structural units used within resist resins for ArF excimer lasers or KrF excimer lasers (and particularly for ArF excimer lasers) can be used.

In the present invention, the component (A) is preferably a copolymer which contains three structural units shown in the following general formula (A-11).

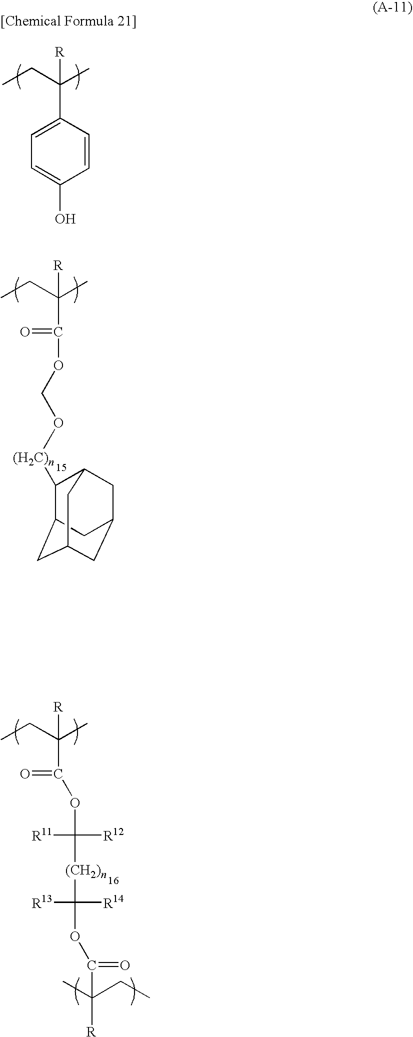

(wherein, R represents a hydrogen atom, a halogen atom, a lower alkyl group or a halogenated lower alkyl group; R¹¹ to R¹⁴ and n₁₆ are respectively as defined for R¹¹ to R¹⁴ and n₁₆ in general formula (a3-1-1) above; and n₁₅ represents 0 or 1.)

In general formula (A-11), R is preferably a hydrogen atom or a methyl group.

R¹¹ to R¹⁴ preferably each independently represents a lower alkyl group of 1 to 5 carbon atoms, and most preferably a methyl group.

n₁₅ is most preferably 0.

n₁₆ is preferably 2 or 3, and most preferably 2.

The component (A) can be obtained, for example, by a conventional radical polymerization or the like of the monomers corresponding with each of the structural units, using a radical polymerization initiator such as azobisisobutyronitrile (AIBN).

Furthermore, in the component (A), by using a chain transfer agent such as a HS—CH₂—CH₂—CH₂—C(CF₃)₂—OH, a —C(CF₃)₂—OH group can be introduced at the terminals of the component (A). Such a copolymer having introduced a hydroxyalkyl group in which a part of the hydrogen atoms of the alkyl group are substituted with fluorine atoms is effective in reducing LWR (line width roughness). Such a copolymer is also effective in reducing developing defects and LER (line edge roughness: unevenness of the side walls of a line pattern).

The weight average molecular weight (Mw) (the polystyrene equivalent value determined by gel permeation chromatography (GPC)) of the component (A) is not particularly limited, but is preferably 2,000 to 50,000, more preferably 3,000 to 30,000, and most preferably 5,000 to 20,000. By making the weight average molecular weight no more than the upper limit of the above-mentioned range, the component (A) exhibits satisfactory solubility in a resist solvent when used as a resist. On the other hand, by making the weight average molecular weight at least as large as the lower limit of the above-mentioned range, dry etching resistance and cross-sectional shape of the resist pattern becomes satisfactory.

Further, the dispersity (Mw/number average molecular weight (Mn)) is not particularly limited, but is preferably 1.0 to 5.0, more preferably 1.0 to 3.0, and most preferably 1.2 to 2.5.

### <Component (B)>

As the component (B), there is no particular limitation, and any of the known acid generators used in conventional chemically amplified resist compositions can be used. Examples of these acid generators are numerous, and include onium salt-based acid generators such as iodonium salts and sulfonium salts; oxime sulfonate-based acid generators; diazomethane-based acid generators such as bisalkyl or bisaryl sulfonyl diazomethanes and poly(bis-sulfonyl)diazomethanes; nitrobenzylsulfonate-based acid generators; iminosulfonate-based acid generators; and disulfone-based acid generators.

As an onion salt-based acid generator, for example, a compound represented by general formula (b-0) shown below can be used.

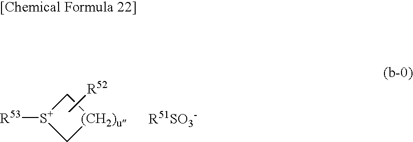

(wherein, R⁵¹ represents a linear, branched or cyclic alkyl group, or a linear, branched or cyclic fluorinated alkyl group; R⁵² represents a hydrogen atom, a hydroxyl group, a halogen atom, a linear or branched alkyl group, a linear or branched halogenated alkyl group, or a linear or branched alkoxy group; R⁵³ represents an aryl group which may have a substituent; and u″ represents an integer of 1 to 3.)

In general formula (b-0), R⁵¹ represents a linear, branched or cyclic alkyl group, or a linear, branched or cyclic fluorinated alkyl group.

The linear or branched alkyl group preferably has 1 to 10 carbon atoms, more preferably 1 to 8 carbon atoms, and most preferably 1 to 4 carbon atoms.

The cyclic alkyl group preferably has 4 to 12 carbon atoms, more preferably 5 to 10 carbon atoms, and most preferably 6 to 10 carbon atoms.

The fluorinated alkyl group preferably has 1 to 10 carbon atoms, more preferably 1 to 8 carbon atoms, and most preferably 1 to 4 carbon atoms.

The fluorination ratio of the fluorinated alkyl group (percentage of the number of fluorine atoms substituting the hydrogen atoms, based on the total number of all hydrogen atoms within the alkyl group) is preferably from 10 to 100%, more preferably from 50 to 100%, and it is particularly desirable that all of the hydrogen atoms are substituted with fluorine atoms, as the acid strength increases.

R⁵¹ is most preferably a linear alkyl group or a linear fluorinated alkyl group.

R⁵² represents a hydrogen atom, a hydroxyl group, a halogen atom, a linear or branched alkyl group, a linear or branched halogenated alkyl group, or a linear or branched alkoxy group.

Examples of the halogen atom for R⁵² include a fluorine atom, a bromine atom, a chlorine atom and an iodine atom, and a fluorine atom is preferable.

The alkyl group for R⁵² is linear or branched, and preferably has 1 to 5 carbon atoms, more preferably 1 to 4 carbon atoms, and most preferably 1 to 3 carbon atoms.

The halogenated alkyl group for R⁵² is a group in which some or all of the hydrogen atoms of the alkyl group have been substituted with halogen atoms. As the alkyl group of the halogenated alkyl group, the same linear or branched alkyl groups as those for R⁵² may be used. As the halogen atoms for substituting the hydrogen atoms of the alkyl group, the same halogen atoms as those for R⁵² may be used. In the halogenated alkyl group, it is preferable that 50 to 100% of the hydrogen atoms of the alkyl group be substituted with halogen atoms, and it is more preferable that all of the hydrogen atoms are substituted with halogen atoms.

The alkoxy group for R⁵² is linear or branched, and preferably has 1 to 5 carbon atoms, more preferably 1 to 4 carbon atoms, and most preferably 1 to 3 carbon atoms.

Among these, as R⁵², a hydrogen atom is particularly desirable.

R⁵³ represents an aryl group which may have a substituent, and examples of the basic ring excluding the substituent include a naphthyl group, a phenyl group and an anthracenyl group. In terms of the effects of the present invention and absorption of exposure ray such as ArF excimer laser, a phenyl group is preferable.

Examples of the substituent include a hydroxyl group and a lower alkyl group (linear or branched, and preferably has 1 to 5 carbon atoms, and a methyl group is particularly desirable).

As the aryl group for A⁵³, those which do not have a substituent are preferable. u″ is an integer of 1 to 3, preferably 2 or 3, and it is particularly desirable that u″ be 3.

As preferable examples of acid generators represented by general formula (b-0), the following can be used.

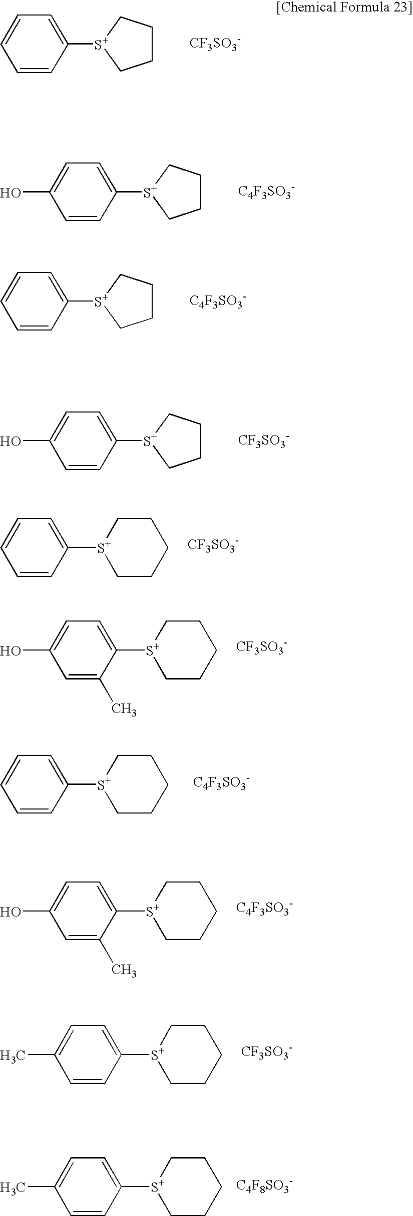

As an onium salt-based acid generator other than those represented by general formula (b-0), a compound represented by general formula (b-1) or (b-2) shown below can be preferably used.

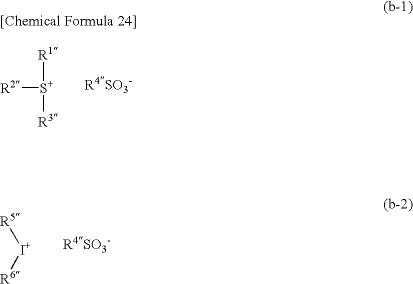

(wherein, R^{1″} to R^{3″}, R^{5″} and R^{6″} each independently represents an aryl group or alkyl group; and R^{4″} represents a linear, branched or cyclic alkyl group or a linear, branched or cyclic fluorinated alkyl group, with the proviso that at least one of R^{1″} to R^{3″} represents an aryl group, and at least one of R^{5″} and R^{6″} represents an aryl group.)

In formula (b-1), R^{1″} to R^{3″} each independently represents an aryl group or an alkyl group. Further, among R^{1″} to R^{3″}, at least one group represents an aryl group. Among R^{1″} to R^{3″}, two or more groups are preferably aryl groups, and it is particularly desirable that all of R^{1″} to R^{3″} are aryl groups.

The aryl group for R^{1″} to R^{3″} is not particularly limited. For example, an aryl group having 6 to 20 carbon atoms may be used in which some or all of the hydrogen atoms of the aryl group may or may not be substituted with alkyl groups, alkoxy groups, or halogen atoms. The aryl group is preferably an aryl group having 6 to 10 carbon atoms because it can be synthesized at a low cost. Specific examples thereof include a phenyl group and naphthyl group.

The alkyl group, with which hydrogen atoms of the aryl group may be substituted, is preferably an alkyl group having 1 to 5 carbon atoms, and most preferably a methyl group, an ethyl group, a propyl group, an n-butyl group, or a tert-butyl group.

The alkoxy group, with which hydrogen atoms of the aryl group may be substituted, is preferably an alkoxy group having 1 to 5 carbon atoms, and most preferably a methoxy group or an ethoxy group.

The halogen atom, with which hydrogen atoms of the aryl group may be substituted, is preferably a fluorine atom.

The alkyl group for R^{1″} to R^{3″} is not particularly limited and includes, for example, a linear, branched or cyclic alkyl group having 1 to 10 carbon atoms. In terms of achieving excellent resolution, the alkyl group preferably has 1 to 5 carbon atoms. Specific examples thereof include a methyl group, an ethyl group, an n-propyl group, an isopropyl group, an n-butyl group, an isobutyl group, an n-pentyl group, a cyclopentyl group, a hexyl group, a cyclohexyl group, a nonyl group, and a decanyl group, and a methyl group is most preferable because it is excellent in resolution and can be synthesized at a low cost.

It is particularly desirable that each of R^{1″} to R^{3″} is a phenyl group or a naphthyl group.

R^{4″} represents a linear, branched or cyclic alkyl group or a linear, branched or cyclic fluorinated alkyl group.

The linear or branched alkyl group preferably has 1 to 10 carbon atoms, more preferably 1 to 9 carbon atoms, and most preferably 1 to 4 carbon atoms.

The cyclic alkyl group is preferably a cyclic group, as described for R^{1″}, having 4 to 15 carbon atoms, more preferably 4 to 10 carbon atoms, and most preferably 6 to 10 carbon atoms.

The fluorinated alkyl group preferably has 1 to 10 carbon atoms, more preferably 1 to 8 carbon atoms, and most preferably 1 to 4 carbon atoms.

Further, the fluorination ratio of the fluorinated alkyl group (percentage of fluorine atoms within the alkyl group) is preferably from 10 to 100%, more preferably from 50 to 100%, and it is particularly desirable that all hydrogen atoms are substituted with fluorine atoms because the acid strength increases.

R^{4″} is most preferably a linear or cyclic alkyl group, or a linear or cyclic fluorinated alkyl group.

In formula (b-2), R^{5″} and R^{6″} each independently represents an aryl group or an alkyl group. At least one of R^{5″} and R^{6″} represents an aryl group. It is preferable that both of R^{5″} and R^{6″} represent an aryl group.

As the aryl group for R^{5″} and R^{6″}, the same aryl groups as those for R^{1″} to R^{3″} can be used.

As the alkyl group for R^{5″} and R^{6″}, the same alkyl groups as those for R^{1″} to R^{3″} can be used.

It is particularly desirable that both of R^{5″} and R^{6″} represents a phenyl group.

As R^{4″} in formula (b-2), the same as those mentioned above for R^{4″} in formula (b-1) can be used.

Specific examples of suitable onium salt-based acid generators represented by formula (b-1) or (b-2) include diphenyliodonium trifluoromethanesulfonate or nonafluorobutanesulfonate; bis(4-tert-butylphenyl)iodonium trifluoromethanesulfonate or nonafluorobutanesulfonate; triphenylsulfonium trifluoromethanesulfonate, heptafluoropropanesulfonate or nonafluorobutanesulfonate; tri(4-methylphenyl)sulfonium trifluoromethanesulfonate, heptafluoropropanesulfonate or nonafluorobutanesulfonate; dimethyl(4-hydroxynaphthyl)sulfonium trifluoromethanesulfonate, heptafluoropropanesulfonate or nonafluorobutanesulfonate; monophenyldimethylsulfonium trifluoromethanesulfonate, heptafluoropropanesulfonate or nonafluorobutanesulfonate; diphenylmonomethylsulfonium trifluoromethanesulfonate, heptafluoropropanesulfonate or nonafluorobutanesulfonate; (4-methylphenyl)diphenylsulfonium trifluoromethanesulfonate, heptafluoropropanesulfonate or nonafluorobutanesulfonate; (4-methoxyphenyl)diphenylsulfonium trifluoromethanesulfonate, heptafluoropropanesulfonate or nonafluorobutanesulfonate; tri(4-tert-butyl)phenylsulfonium trifluoromethanesulfonate, heptafluoropropanesulfonate or nonafluorobutanesulfonate; diphenyl(1-(4-methoxy)naphthyl)sulfonium trifluoromethanesulfonate, heptafluoropropanesulfonate or nonafluorobutanesulfonate; and di(1-naphthyl)phenylsulfonium trifluoromethanesulfonate, heptafluoropropanesulfonate or nonafluorobutanesulfonate. It is also possible to use onium salts in which the anion moiety of these onium salts are replaced by methanesulfonate, n-propanesulfonate, n-butanesulfonate, or n-octanesulfonate.

Further, onium salt-based acid generators in which the anion moiety in general formula (b-1) or (b-2) is replaced by an anion moiety represented by general formula (b-3) or (b-4) shown below (the cation moiety is the same as (b-1) or (b-2)) may also be used.

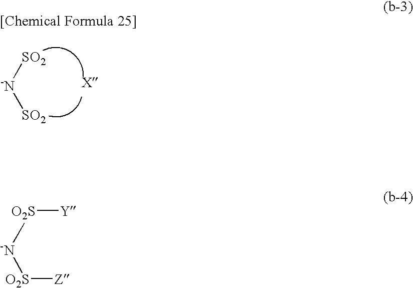

(wherein, X″ represents an alkylene group of 2 to 6 carbon atoms in which at least one hydrogen atom has been substituted with a fluorine atom; and Y″ and Z″ each independently represents an alkyl group of 1 to 10 carbon atoms in which at least one hydrogen atom has been substituted with a fluorine atom.)

X″ represents a linear or branched alkylene group in which at least one hydrogen atom has been substituted with a fluorine atom, and the alkylene group has 2 to 6 carbon atoms, preferably 3 to 5 carbon atoms, and most preferably 3 carbon atoms.

Y″ and Z″ each independently represents a linear or branched alkyl group in which at least one hydrogen atom has been substituted with a fluorine atom, and the alkyl group has 1 to 10 carbon atoms, preferably 1 to 7 carbon atoms, and more preferably 1 to 3 carbon atoms.

Reducing the number of carbon atoms of the alkylene group for X″ or those of the alkyl group for Y″ and Z″ within the above-mentioned range of the number of carbon atoms is preferable since the solubility in a resist solvent is improved.

Further, in the alkylene group for X″ or the alkyl group for Y″ and Z″, it is preferable that the number of hydrogen atoms substituted with fluorine atoms is as large as possible, because the acid strength increases and the transparency to high energy radiation of 200 nm or less, or electron beam is improved. The percentage of the fluorine atoms within the alkylene group or alkyl group, i.e., the fluorination ratio, is preferably from 70 to 100%, more preferably from 90 to 100%, and it is particularly desirable that the alkylene group or alkyl group be a perfluoroalkylene or perfluoroalkyl group in which all hydrogen atoms are substituted with fluorine atoms.

In the present description, an oximesulfonate-based acid generator is a compound having at least one group represented by general formula (B-1) shown below, and has a feature of generating acid by irradiation. Such oximesulfonate-based acid generators are widely used for a chemically amplified resist composition, and can be appropriately selected.

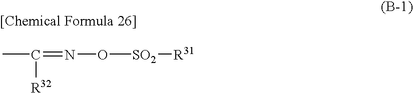

(wherein, R³¹ and R³² each independently represents an organic group.)

The organic group for R³¹ and R³² refers to a group containing a carbon atom, and may include atoms other than carbon atoms (ergo, a hydrogen atom, an oxygen atom, a nitrogen atom, a sulfur atom, a halogen atom (such as a fluorine atom and a chlorine atom) and the like).

As the organic group for R³¹, a linear, branched, or cyclic alkyl group or aryl group is preferable. The alkyl group or the aryl group may have a substituent. The substituent is not particularly limited, and examples thereof include a fluorine atom and a linear, branched, or cyclic alkyl group having 1 to 6 carbon atoms. The expression “having a substituent” means that some or all of the hydrogen atoms of the alkyl group or the aryl group are substituted with substituents.

The alkyl group preferably has 1 to 20 carbon atoms, more preferably 1 to 10 carbon atoms, still more preferably 1 to 8 carbon atoms, still more preferably 1 to 6 carbon atoms, and most preferably 1 to 4 carbon atoms. As the alkyl group, a partially or completely halogenated alkyl group (hereinafter, sometimes referred to as a “halogenated alkyl group”) is particularly desirable. The “partially halogenated alkyl group” refers to an alkyl group in which some of the hydrogen atoms are substituted with halogen atoms, and the “completely halogenated alkyl group” refers to an alkyl group in which all of the hydrogen atoms are substituted with halogen atoms. Examples of the halogen atom include a fluorine atom, a chlorine atom, a bromine atom and an iodine atom, and a fluorine atom is particularly desirable. In other words, the halogenated alkyl group is preferably a fluorinated alkyl group.

The aryl group preferably has 4 to 20 carbon atoms, more preferably 4 to 10 carbon atoms, and most preferably 6 to 10 carbon atoms. As the aryl group, a partially or completely halogenated aryl group is particularly desirable. The “partially halogenated aryl group” refers to a aryl group in which some of the hydrogen atoms are substituted with halogen atoms, and the “completely halogenated aryl group” refers to an aryl group in which all of the hydrogen atoms are substituted with halogen atoms.

As R³¹, an alkyl group of 1 to 4 carbon atoms which has no substituent or a fluorinated alkyl group of 1 to 4 carbon atoms is particularly desirable.

As the organic group for R³², a linear, branched, or cyclic alkyl group, aryl group, or cyano group is preferable. Examples of the alkyl group and the aryl group for R³² are the same as those of the alkyl group and the aryl group for R³¹.

As R³², a cyano group, an alkyl group of 1 to 8 carbon atoms having no substituent or a fluorinated alkyl group of 1 to 8 carbon atoms is particularly desirable.

Preferred examples of the oxime sulfonate-based acid generator include compounds represented by general formula (B-2) or (B-3) shown below,

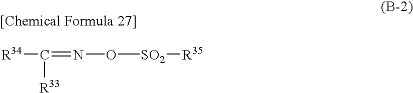

(wherein, R³³ represents a cyano group, an alkyl group having no substituent or a halogenated alkyl group; R³⁴ represents an aryl group; and R³⁵ represents an alkyl group having no substituent or a halogenated alkyl group.)

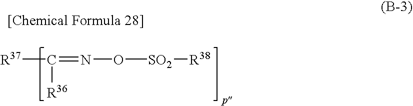

(wherein, R³⁶ represents a cyano group, an alkyl group having no substituent or a halogenated alkyl group; R³⁷ represents a divalent or trivalent aromatic hydrocarbon group; R³⁸ represents an alkyl group having no substituent or a halogenated alkyl group; and p″ represents 2 or 3.)

In general formula (B-2), the alkyl group having no substituent or the halogenated alkyl group for R³³ preferably has 1 to 10 carbon atoms, more preferably 1 to 8 carbon atoms, and most preferably 1 to 6 carbon atoms.

As R³³, a halogenated alkyl group is preferable, and a fluorinated alkyl group is more preferable.

The fluorinated alkyl group for R³³ preferably has 50% or more of the hydrogen atoms thereof fluorinated, more preferably 70% or more, and still more preferably 90% or more.

Examples of the aryl group for R³⁴ include groups in which one hydrogen atom has been removed from an aromatic hydrocarbon ring, such as a phenyl group, a biphenyl group, a fluorenyl group, a naphtyl group, an anthracyl group, and a phenanthryl group; and heteroaryl groups in which some of the carbon atoms constituting the ring(s) of these groups are substituted with hetero atoms such as an oxygen atom, a sulfur atom, and a nitrogen atom. Of these, a fluorenyl group is preferable.

The aryl group for R³⁴ may have a substituent such as an alkyl group of 1 to 10 carbon atoms, a halogenated alkyl group of 1 to 10 carbon atoms, or an alkoxy group of 1 to 10 carbon atoms. The alkyl group and halogenated alkyl group as the substituent preferably has 1 to 8 carbon atoms, and more preferably 1 to 4 carbon atoms. The halogenated alkyl group is preferably a fluorinated alkyl group.

The alkyl group having no substituent or the halogenated alkyl group for R³⁵ preferably has 1 to 10 carbon atoms, more preferably 1 to 8 carbon atoms, and most preferably 1 to 6 carbon atoms.

As R³⁵, a halogenated alkyl group is preferable, and a partially or completely fluorinated alkyl group is more preferable.

In terms of enhancing the strength of the acid generated, the fluorinated alkyl group for R³⁵ preferably has 50% or more of the hydrogen atoms fluorinated, more preferably 70% or more, still more preferably 90% or more. A completely fluorinated alkyl group in which 100% of the hydrogen atoms are substituted with fluorine atoms is particularly desirable.

In general formula (B-3), the alkyl group having no substituent and the halogenated alkyl group for R³⁶ are the same as the alkyl group having no substituent and the halogenated alkyl group for R³³.

Examples of the divalent or trivalent aromatic hydrocarbon group for R³⁷ include groups in which one or two hydrogen atoms have been removed from the aryl group for R³⁴.

As the alkyl group having no substituent or the halogenated alkyl group for R³⁸, the same alkyl group having no substituent or halogenated alkyl group as those for R³⁵ can be used.

p″ is preferably 2.

Specific examples of oxime sulfonate-based acid generators include α-(p-toluenesulfonyloxyimino)-benzyl cyanide, α-(p-chlorobenzenesulfonyloxyimino)-benzyl cyanide, α-(4-nitrobenzenesulfonyloxyimino)-benzyl cyanide, α-(4-nitro-2-trifluoromethylbenzenesulfonyloxyimino)-benzyl cyanide, α-(benzenesulfonyloxyimino)-4-chlorobenzyl cyanide, α-(benzenesulfonyloxyimino)-2,4-dichlorobenzyl cyanide, α-(benzenesulfonyloxyimino)-2,6-dichlorobenzyl cyanide, α-(enzenesulfonyloxyimino)-4-methoxybenzyl cyanide, α-(2-chlorobenzenesulfonyloxyimino)-4-methoxybenzyl cyanide, α-(benzenesulfonyloxyimino)-thien-2-yl acetonitrile, α-(4-dodecylbenzenesulfonyloxyimino)benzyl cyanide, α-[(p-toluenesulfonyloxyimino)-4-methoxyphenyl]acetonitrile, α-[(dodecylbenzenesulfonyloxyimino)-4-methoxyphenyl]acetonitrile, α-(tosyloxyimino)-4-thienyl cyanide, α-(methylsulfonyloxyimino)-1-cyclopentenyl acetonitrile, α-(methylsulfonyloxyimino)-1-cyclohexenyl acetonitrile, α-(methylsulfonyloxyimino)-1-cycloheptenyl acetonitrile, α-(methylsulfonyloxyimino)-1-cyclooctenyl acetonitrile, α-(trifluoromethylsulfonyloxyimino)-1-cyclopentenyl acetonitrile, α-(trifluoromethylsulfonyloxyimino)-cyclohexyl acetonitrile, α-(ethylsulfonyloxyimino)-ethyl acetonitrile, α-propylsulfonyloxyimino)-propyl acetonitrile, α-(cyclohexylsulfonyloxyimino)-cyclopentyl acetonitrile, α-(cyclohexylsulfonyloxyimino)-cyclohexyl acetonitrile, α-(cyclohexylsulfonyloxyimino)-1-cyclopentenyl acetonitrile, α-(ethylsulfonyloxyimino)-1-cyclopentenyl acetonitrile, α-(isopropylsulfonyloxyimino)-1-cyclopentenyl acetonitrile, α-(n-butylsulfonyloxyimino)-1-cyclopentenyl acetonitrile, α-(ethylsulfonyloxyimino)-1 cyclohexenyl acetonitrile, α-(isopropylsulfonyloxyimino)-1-cyclohexenyl acetonitrile, α-(n-butylsulfonyloxyimino)-1-cyclohexenyl acetonitrile, α-(methylsulfonyloxyimino)-phenyl acetonitrile, α-(methylsulfonyloxyimino)-p-methoxyphenyl acetonitrile, α-(trifluoromethylsulfonyloxyimino)-phenyl acetonitrile, α-(trifluoromethylsulfonyloxyimino)-p-methoxyphenyl acetonitrile, α-(ethylsulfonyloxyimino)-p-methoxyphenyl acetonitrile, α-(propylsulfonyloxyimino)-p-methylphenyl acetonitrile, and α-(methylsulfonyloxyimino)-p-bromophenyl acetonitrile.

Further, oxime sulfonate-based acid generators disclosed in Japanese Unexamined Patent Application, First Publication No. Hei 9-208554 (Chemical Formulas 18 and 19 shown in paragraphs [0012] to [0014]) and oxime sulfonate-based acid generators disclosed in WO 2004/074242A2 (Examples 1 to 40 described at pages 65 to 85) may be preferably used.

Furthermore, the following can be suitably used.

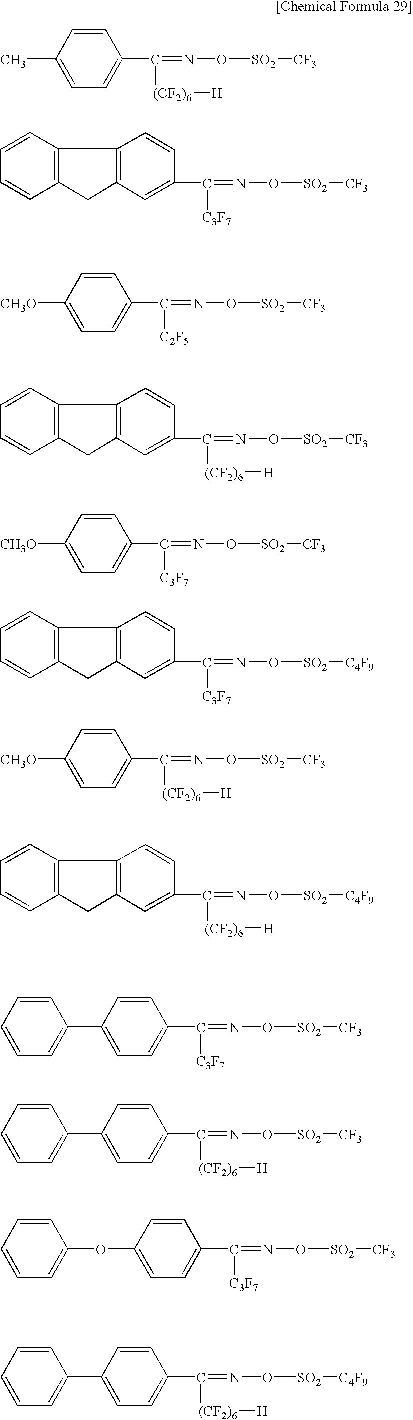

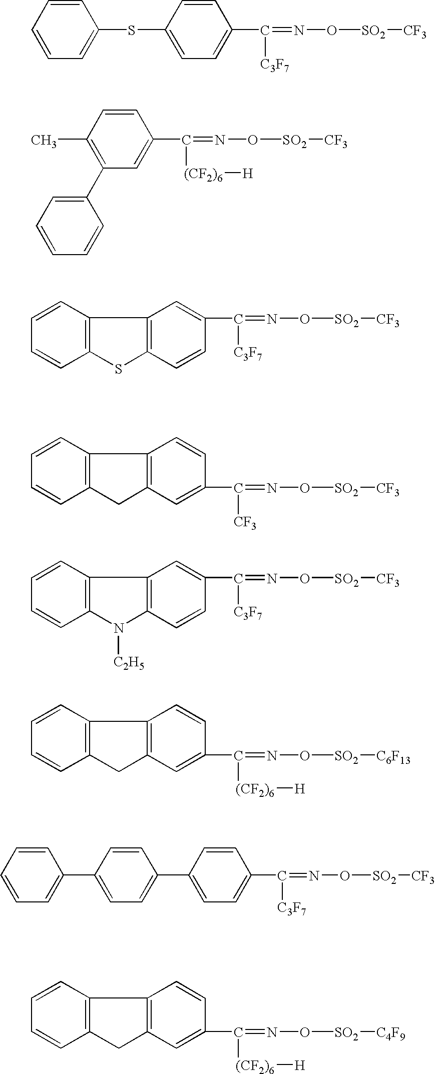

Further, as more preferable examples of oxime sulfonate-based acid generators, the following 4 compounds can be used.

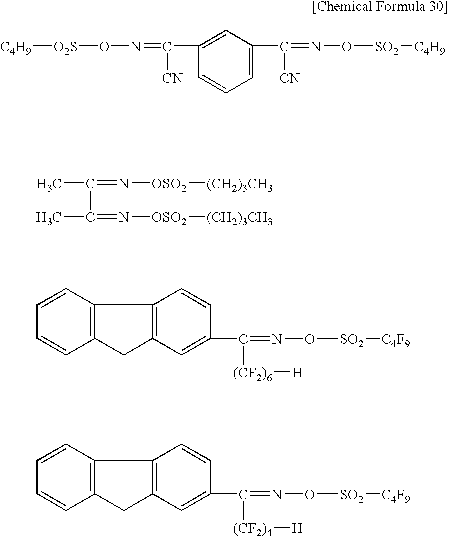

Of the aforementioned diazomethane-based acid generators, specific examples of suitable bisalkyl or bisaryl sulfonyl diazomethanes include bis(isopropylsulfonyl)diazomethane, bis(p-toluenesulfonyl)diazomethane, bis(1,1-dimethylethylsulfonyl)diazomethane, bis(cyclohexylsulfonyl)diazomethane, and bis(2,4-dimethylphenylsulfonyl)diazomethane.

Further, diazomethane-based acid generators disclosed in Japanese Unexamined Patent Application, First Publication No. Hei 11-035551, Japanese Unexamined Patent Application, First Publication No. Hei 11-035552 and Japanese Unexamined Patent Application, First Publication No. Hei 11-035573 may be preferably used.

Furthermore, as poly(bis-sulfonyl)diazomethanes, those disclosed in Japanese Unexamined Patent Application, First Publication No. Hei 11-322707, including
1,3-bis(phenylsulfonyldiazomethylsulfonyl)propane,
1,4-bis(phenylsulfonyldiazomethylsulfonyl)butane,
1,6-bis(phenylsulfonyldiazomethylsulfonyl)hexane,
1,10-bis(phenylsulfonyldiazomethylsulfonyl)decane,
1,2-bis(cyclohexylsulfonyldiazomethylsulfonyl)ethane,
1,3-bis(cyclohexylsulfonyldiazomethylsulfonyl)propane,
1,6-bis(cyclohexylsulfonyldiazomethylsulfonyl)hexane, and
1,10-bis(cyclohexylsulfonyldiazomethylsulfonyl)decane, may be used.

As the component (B), one type of these acid generators may be used alone, or two or more types may be used in combination.

In the present invention, as the component (B), it is particularly preferable to use an onium salt in which an anion is a fluorinated alkylsulfonate ion.

The amount of the component (B) within the positive resist composition of the present invention is preferably 0.5 to 30 parts by weight, and more preferably 1 to 20 parts by weight, relative to 100 parts by weight of the component (A). When the amount of the component (B) is within the above-mentioned range, formation of a resist pattern can be satisfactorily performed. Further, by virtue of the above-mentioned range, a uniform solution can be obtained and the storage stability becomes satisfactory.

### <Component (D)>

For improving the resist pattern shape and the post exposure stability of the latent image formed by the pattern-wise exposure of the resist layer, the positive resist composition of the present invention may further contain a nitrogen-containing organic compound (D)) (hereinafter referred to as the component (D)) as an optional component.

A multitude of these components (D) have already been proposed, and any of these known compounds may be used, although an aliphatic amine, and particularly a secondary aliphatic amine or tertiary aliphatic amine is preferable. Here, an aliphatic amine is an amine having one or more aliphatic groups, and the aliphatic groups preferably have 1 to 12 carbon atoms.

Examples of these aliphatic amines include amines in which at least one hydrogen atom of ammonia (NH₃) has been substituted with an alkyl group or hydroxyalkyl group of 1 to 12 carbon atoms (i.e., alkylamines or alkyl alcohol amines), and cyclic amines.

Specific examples of alkylamines and alkylalcoholamines include monoalkylamines such as n-hexylamine, n-heptylamine, n-octylamine, n-nonylamine, and n-decylamine; dialkylamines such as diethylamine, di-n-propylamine, di-n-heptylamine, di-n-octylamine, and dicyclohexylamine; trialkylamines such as trimethylamine, triethylamine, tri-n-propylamine, tri-n-butylamine, tri-n-hexylamine, tri-n-pentylamine, tri-n-heptylamine, tri-n-octylamine, tri-n-nonylamine, tri-n-decanylamine, and ti-n-dodecylamine; and alkyl alcohol amines such as diethanolamine, triethanolamine, diisopropanolamine, triisopropanolamine, di-n-octanolamine, and tri-n-octanolamine, Among these, trialkylamines of 5 to 10 carbon atoms are preferable, and tri-n-octylamine is particularly desirable.

Examples of the cyclic amine include heterocyclic compounds containing a nitrogen atom as a hetero atom. The heterocyclic compound may be a monocyclic compound (aliphatic monocyclic amine), or a polycyclic compound (aliphatic polycyclic amine).

Specific examples of the aliphatic monocyclic amine include piperidine, and piperazine.

The aliphatic polycyclic amine preferably has 6 to 10 carbon atoms, and specific examples thereof include 1,5-diazabicyclo[4.3.0)]-5-nonene, 1,8-diazabicyclo[5.4.0]-7-undecene, hexamethylenetetramine, and 1,4-diazabicyclo[2.2.2]octane.

Of these, one type may be used alone, or two or more types may be used in combination.

The component (D) is typically used in an amount within a range from 0.01 to 5.0 parts by weight, relative to 100 parts by weight of the component (A).

### <Optional Component>

Furthermore, in the positive resist composition of the present invention, for preventing any deterioration in sensitivity, and improving the resist pattern shape and the post exposure stability of the latent image formed by the pattern-wise exposure of the resist layer, at least one compound (E) hereinafter referred to as the component (E)) selected from the group consisting of an organic carboxylic acid, or a phosphorus oxo acid or derivative thereof can be added as an optional component.

Examples of suitable organic carboxylic acids include acetic acid, malonic acid, citric acid, malic acid, succinic acid, benzoic acid, and salicylic acid.

Examples of phosphorus oxo acids or derivatives thereof include phosphoric acid, phosphonic acid and phosphinic acid. Among these, phosphonic acid is particularly desirable.

Examples of phosphorus oxo acid derivatives include esters in which a hydrogen atom within the above-mentioned oxo acids is substituted with a hydrocarbon group. Examples of the hydrocarbon group include an alkyl group of 1 to 5 carbon atoms and an aryl group of 6 to 15 carbon atoms.

Examples of phosphoric acid derivatives include phosphoric acid esters such as di-n-butyl phosphate and diphenyl phosphate.

Examples of phosphonic acid derivatives include phosphonic acid esters such as dimethyl phosphonate, di-n-butyl phosphonate, phenylphosphonic acid, diphenyl phosphonate and dibenzyl phosphonate.

Examples of phosphinic acid derivatives include phosphinic acid esters such as phenylphosphinic acid.

As the component (E), one type may be used alone, or two or more types may be used in combination.

As the component (E), an organic carboxylic acid is preferable, and salicylic acid is particularly desirable.

The component (E) is typically used in an amount within a range from 0.01 to 5.0 parts by weight, relative to 100 parts by weight of the component (A).

If desired, other miscible additives can also be added to the positive resist composition of the present invention. Examples of such miscible additives include additive resins for improving the performance of the resist film, surfactants for improving the applicability, dissolution inhibitors, plasticizers, stabilizers, colorants, halation prevention agents, and dyes.

The positive resist composition of the present invention can be prepared by dissolving the materials for the resist composition (the component (A), component (B), and if desired, various optional components such as the component (D)) in an organic solvent (hereinafter, frequently referred to as “component (S)”).

The component (S) may be any organic solvent which can dissolve the respective components to give a uniform solution, and any one or more kinds of organic solvents can be appropriately selected from those which have been conventionally known as solvents for a chemically amplified resist.

Examples thereof include lactones such as γ-butyrolactone; ketones such as acetone, methyl ethyl ketone, cyclohexanone, methyl-n-amyl ketone, methyl isoamyl ketone, and 2-heptanone; polyhydric alcohols, such as ethylene glycol, diethylene glycol, propylene glycol and dipropylene glycol; compounds having an ester bond, such as ethylene glycol monoacetate, diethylene glycol monoacetate, propylene glycol monoacetate, and dipropylene glycol monoacetate; polyhydric alcohol derivatives including compounds having an ether bond, such as a monoalkylether (e.g., monomethylether, monoethylether, monopropylether or monobutylether) or monophenylether of any of these polyhydric alcohols or compounds having an ester bond (among these, propylene glycol monomethyl ether acetate (PGMEA) and propylene glycol monomethyl ether (PGME) are preferable); cyclic ethers such as dioxane; esters such as methyl lactate, ethyl lactate (EL), methyl acetate, ethyl acetate, butyl acetate, methyl pyruvate, ethyl pyruvate, methyl methoxypropionate, and ethyl ethoxypropionate; and aromatic organic solvents such as anisole, ethylbenzylether, cresylmethylether, diphenylether, dibenzylether, phenetole, butylphenylether, ethylbenzene, diethylbenzene, amylbenzene, isopropylbenzene, toluene, xylene, cymene and mesitylene.

These organic solvents can be used individually, or in combination as a mixed solvent.

Among these, propylene glycol monomethyl ether acetate (PGMEA), propylene glycol monomethyl ether (PGME) and ethyl lactate (EL) are preferable.

Further, among the mixed solvents, a mixed solvent obtained by mixing PGMEA with a polar solvent is preferable. The mixing ratio (weight ratio) of the mixed solvent can be appropriately determined, taking into consideration the compatibility of the PGMEA with the polar solvent, but is preferably in the range of 1:9 to 9:1, and more preferably from 2:8 to 8:2.

Specifically, when EL is mixed as the polar solvent, the PGMEA:EL weight ratio is preferably from 1:9 to 9:1, and more preferably from 2:8 to 8:2. Alternatively, when PGME is mixed as the polar solvent, the PGMEA:PGME weight ratio is preferably from 1:9 to 9:1, more preferably from 2:8 to 8:2, and still more preferably 3:7 to 7:3.

Further, as the component (S), a mixed solvent of at least one of PGMEA and EL with γ-butyrolactone is also preferable. The mixing ratio (former:latter) of such a mixed solvent is preferably from 70:30 to 95:5.

The amount of the component (S) used is not particularly limited, and is appropriately adjusted to a concentration which enables coating of a coating solution to a substrate, depending on the thickness of the coating film. In general, the component (S) is used in an amount such that the solid content of the resist composition becomes within the range from 2 to 20% by weight, and preferably from 5 to 15% by weight.

### <<Method of Forming a Resist Pattern>>

The method of forming a resist pattern according to the present invention includes: forming a resist film on a substrate using a positive resist composition of the present invention; subjecting the resist film to exposure; and developing the resist film to form a resist pattern.

More specifically, the method for forming a resist pattern according to the present invention can be performed, for example, as follows.

Firstly, the positive resist composition is applied onto a substrate such as a silicon wafer using a spinner or the like, and a prebake (post applied bake (PAB)) is conducted under temperature conditions of 80 to 150° C. for 40 to 120 seconds, preferably 60 to 90 seconds to form a resist film. Then, using an exposure apparatus or the like, the resist film is selectively exposed by irradiation with extreme ultraviolet rays (EUV), a KrF excimer laser beam, or the like trough a desired mask pattern, or by direct irradiation with an electron beam (patterning of the resist film) without using a mask pattern. This is followed by post exposure bake (PEB) under temperature conditions of 80 to 150° C. for 40 to 120 seconds, preferably 60 to 90 seconds. Subsequently, developing is conducted using an alkali developing solution such as a 0.1 to 10% by weight aqueous solution of tetramethylammonium hydroxide. In this manner, a resist pattern can be obtained.

An organic or inorganic antireflection film may be provided between the substrate and the applied coating layer of the resist composition.

The wavelength to be used for exposure is not particularly limited and the exposure can be conducted using radiations such as AF excimer laser, KrF excimer laser, F₂ excimer laser, extreme ultraviolet rays (EUV), vacuum ultraviolet rays (VUV), electron beam (EB), X-rays, and soft X-rays. The positive resist composition of the present invention is particularly effective to the lithography processes using KrF excimer laser, EUV, or EB.

Due to the positive resist composition and method of forming a resist pattern according to the present invention, a resist pattern with excellent resolution can be formed.

It is considered that improvements in the resolution are achieved due to the following. The component (A) includes an alkali soluble structural unit (a1), a structural unit (a2) having an acetal-type acid dissociable dissolution inhibiting group in the side chain portion of acrylic acid therein, and a structural unit (a3) that dissociates under action of acid generated from the component (B). Accordingly, differences in alkali solubility (solubility contrast) between the unexposed portions and the exposed portions increase.

That is, the acetal-type acid dissociable dissolution inhibiting group of the structural unit (82) exhibits a low activation energy during the deprotection reaction, and thus, is easily dissociated. For this reason, the rate of dissociation of the acid dissociable dissolution inhibiting groups existing in the exposed portions (deprotection rate) upon exposure is high, and thus alkali solubility of the exposed portions remarkably increases.

Furthermore, the structural unit (a3) substantially constitutes a cross-linking structure that links a plurality of polymer chains constituted of a plurality of structural units (a1) and (a2). As described earlier, the structural unit (a3) dissociates due to the action of acid generated from the component (B). Therefore, in the formation of a resist pattern, by conducting a selective exposure of a resist film formed by applying the positive resist composition of the present invention onto a substrate, the action of acid generated from the component (B) dissociates the structural unit (a3) in the exposed portions. Due to the dissociation of the structural unit (a3), a plurality of carboxyl groups are generated and the weight average molecular weight of the component (A) reduces considerably, and thus alkali solubility of the exposed portions increases. On the other hand, the alkali solubility of the unexposed portions remains low since the structural unit (a3) stays intact without dissociation. As a result, solubility contrast of the component (A) increases considerably compared to the case where the component (A) does not contain the structural unit (a3), and it is considered that this increase in the solubility contrast is contributing to the improvements in resolution.

Furthermore, in the present invention, the shape of the obtained resist pattern is also satisfactory, and, for example, a resist pattern with minimal surface roughness can be formed. Roughness has the potential to adversely affect the formation of very fine semiconductor elements. For example, roughness on the side wall surfaces of a resist pattern, so-called line edge roughness (LER), can cause distortions around the holes in hole patterns, and fluctuations of the line width in line and space patterns. This problem of roughness becomes more significant as the pattern dimensions are reduced. Since the lithography processes using electron beams, EUV or the like are targeting the formation of very fine patterns with dimensions of several dozen nm, the improvement in roughness will be highly important.

Moreover, in the present invention, thickness loss within the formed resist pattern is minimal. The term “thickness loss” refers to an extent of change in the thickness of the resist film before and after the developing process, and the resist film becomes more useful for the process in which etching is conducted using the resist pattern as a mask, as the extent of thickness loss reduces.

Similar to the aforementioned effects, it is considered that these effects are achieved due to enhancements in solubility contrast.

### EXAMPLES

As follows is a description of Examples of the present invention, although the scope of the present invention is by no way limited by these Examples.

In Example 1 and Comparative Example 1 described below, resins (A)-1 and (A)-2 synthesized by a copolymerization of the following monomers (1) to (3) using a conventional dropwise polymerization method were used.

This process is described in more detail using the synthesis of the resin (A)-1 as an example. Propylene glycol monomethyl ether acetate (PGMEA) was added into a flask equipped with an inlet for nitrogen, a stirrer, a condenser and a thermometer under a nitrogen atmosphere, and the temperature of the water bath was elevated to 80° C. while stirring. Subsequently, 2,2′-azobisisobutyronitrile (AIBN) as a polymerization initiator, and a monomer/PGMEA solution obtained by mixing so that the ratio of the monomers within the solution was monomer (1)/monomer (2)/monomer (3)=7/2.5/0.5 (molar ratio), were dropwise added into the flask using a dripping apparatus at a constant rate over 6 hours, and then the temperature was maintained at 80° C. for 1 hour. Then, the temperature of the reaction liquid was cooled to room temperature. Subsequently, the resulting reaction liquid was dropwise added to methanol about 30 times in amount while stirring, to obtain a colorless precipitate. The obtained precipitate was subjected to filtration, and then the precipitate was washed in methanol in an amount about 30 times the amount of the monomers used in the polymerization. The obtained precipitate was subjected to filtration, and then the precipitate was dissolved in tetrahydrofuran (THF). An 80% by weight aqueous solution of hydrazine was dropwise added to the obtained THF solution and the mixed liquid was stirred at 25° C. for 1 hour. Following the completion of the reaction, the resulting reaction liquid was dropwise added in a large amount of water to obtain a precipitate. The resulting precipitate was subjected to filtration, and then the precipitate was washed and then dried under reduced pressure at 50° C. for about 40 hours to obtain the resin (A)-1.

The resin (A)-2 was synthesized in substantially the same manner as in the above method for synthesizing the resin (A)-1, except that the types of monomers which derive the respective structural units and the amounts thereof used were changed.

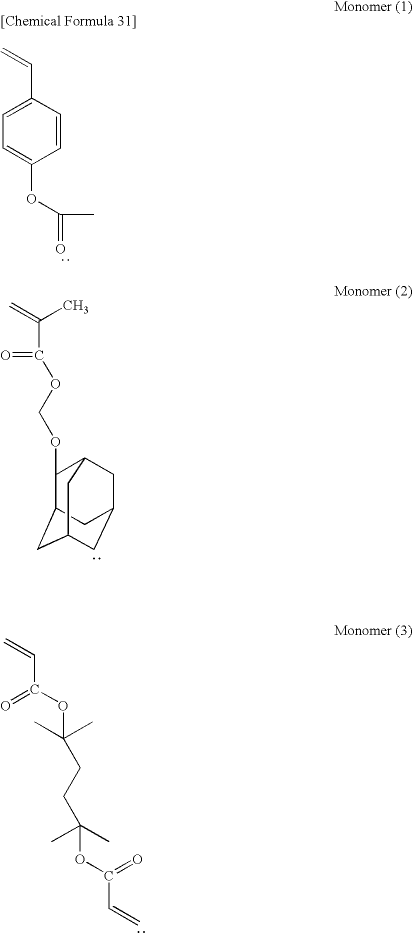

The structure of the resin (A)-1 is shown below.

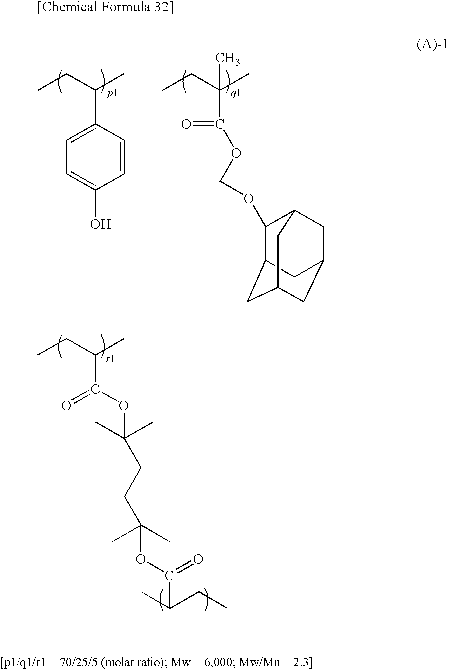

The structure of the resin (A)-2 is shown below.

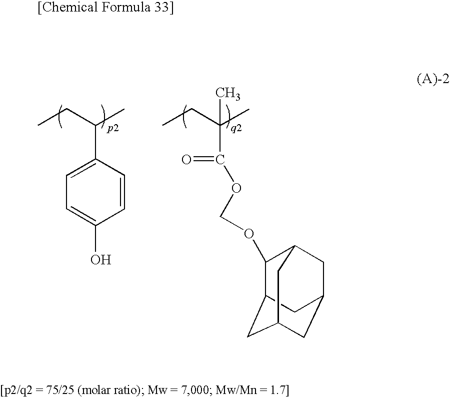

### Examples 1 to 3, Comparative Example 1

The components shown in Table 1 were mixed together and dissolved to obtain positive resist composition solutions.

TABLE 1

| | Compo- | Compo- | Compo- | Compo- | |
|---|---|---|---|---|---|
| | nent (A) | nent (B) | nent (D) | nent (E) | Component (S) |
| Example 1 | (A)-1 | (B)-1 | (D)-1 | (E)-1 | (S)-1 |
| | [100] | [12.60] | [0.38] | [0.15] | [2000] |
| Example 2 | (A)-1 | (B)-1 | (D)-1 | (E)-1 | (S)-1 |
| | [100] | [12.60] | [1.07] | [0.43] | [2000] |
| Example 3 | (A)-1 | (B)-2 | (D)-1 | (E)-1 | (S)-1 |
| | [100] | [12.40] | [1.07] | [0.43] | [2000] |
| Comparative | (A)-2 | (B)-1 | (D)-1 | (E)-1 | (S)-1 |
| Example 1 | [100] | [12.60] | [1.07] | [0.43] | [2000] |

In Table 2, the abbreviations indicate the following. Further, the values within brackets [ ] indicate the amount (parts by weight) of the component added.

(B)-1: a compound represented by formula (B)-1 shown below
(B)-2: a compound represented by formula (B)-2 shown below
(D)-1: tri-n-octylamine
(E)-1: salicylic acid

### (S)-1: PGMEA

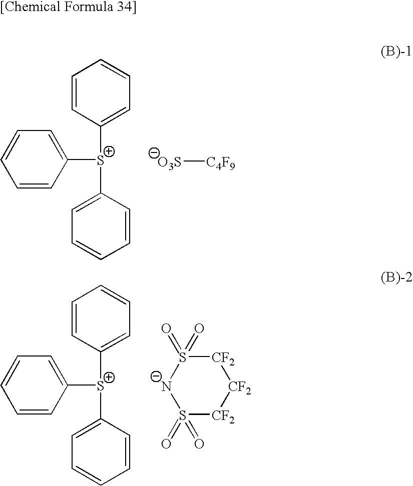

Each of the thus obtained positive resist composition solutions was applied uniformly to the surface of an 8-inch silicon substrate, and was then subjected to a prebake treatment (PAB) at 100° C. for 90 seconds, thus forming a resist film with a film thickness of 100 nm.

The obtained resist film was then subjected to direct patterning with an electron beam lithography apparatus (product name: HM800D, manufactured by Hitachi Ltd., accelerating voltage: 70 kV), and was then subjected to a bake treatment (PEB) at 110° C. for 90 seconds, developed for 60 seconds in a 2.38% by weight aqueous tetramethylammonium hydroxide (TMAH) solution at 23° C., rinsed in pure water for 30 seconds, and shaken dry to form a line and space pattern (hereinafter referred to as “L/S pattern”).

In this manner, the optimum exposure dose (EOP, μC/cm²) for forming a L/S pattern having a line width of 100 nm and a pitch of 200 nm was determined and the critical resolution at the EOP was determined. The results are shown in Table 2.

TABLE 2

| | EOP | Critical |
|---|---|---|
| | (μC/cm²) | resolution (nm) |
| Example 1 | 28 | 50 |
| Example 2 | 28 | 50 |
| Example 3 | 32 | 50 |
| Comparative Example 1 | 16 | 70 |

As seen from the results shown above, it was possible to form resist patterns with high resolutions by using the positive resist compositions of Examples 1 to 3.

The cross-sectional shape of the formed L/S patterns was observed by a scanning electron microscope (SEM). As a result, it was found that in the shape of the L/S patterns of Examples 1 to 3, unevenness of the side walls of a line pattern or unevenness of the pattern surface was minimal, and thus, the cross-sectional shape was excellent. On the other hand, the shape of the L/S patterns of Comparative Example 1 was more uneven in the side walls of a line pattern or in the pattern surface compared to that of Examples 1 to 3.

### INDUSTRIAL APPLICABILITY

According to the present invention, there are provided a positive resist composition which is capable of forming a resist pattern with excellent resolution, and a method of forming a resist pattern. Therefore, the present invention is extremely useful in industry.

1. A positive resist composition comprising a resin component (A) which exhibits increased solubility in ma alkali developing solution under action of acid and an acid-generator component (B) which generates acid upon exposure,
the resin component (A) comprising a structural unit (a1) derived from hydroxystyrene, a structural unit (a2) represented by general formula (a2-1) or (a2-2) shown below, and a structural unit (a3) represented by general formula (a3-1) or (a3-2) shown below: 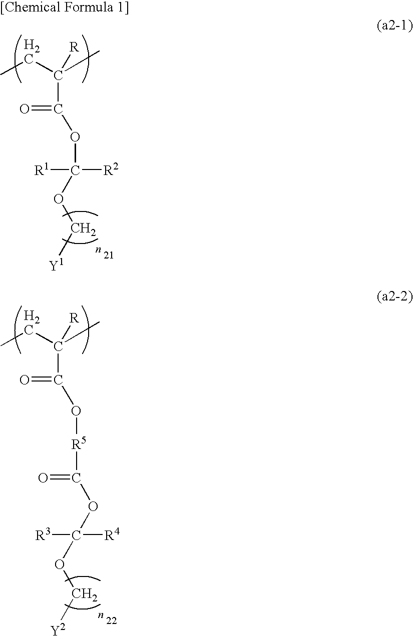
(in general formula (a2-1), R represents a hydrogen atom, a halogen atom, a lower alkyl group or a halogenated lower alkyl group; R¹ and R² each independently represents a hydrogen atom or a lower alkyl group; Y¹ represents a lower alkyl group or a monovalent aliphatic cyclic group; and n₂₁ represents an integer of 0 to 3, and
in general formula (a2-2), R represents a hydrogen atom, a halogen atom, a lower alkyl group or a halogenated lower alkyl group; R³ and R⁴ each independently represents a hydrogen atom or a lower alkyl group; R⁵ represents an alkylene group or a divalent aliphatic cyclic group; Y² represents a lower alkyl group or a monovalent aliphatic cyclic group; and n₂₂ represents an integer of 0 to 3), 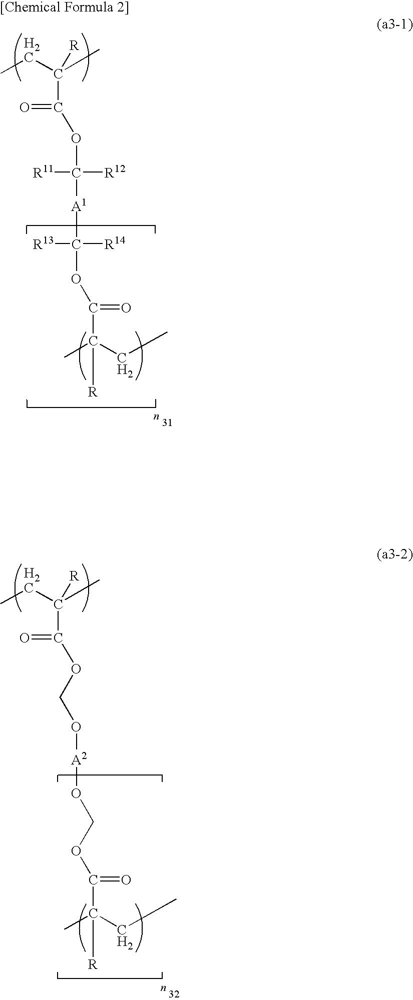
(in general formula (a3-1), R represents a hydrogen atom, a halogen atom, a lower alkyl group or a halogenated lower alkyl group and the plurality of R may be the same or different; R¹¹ to R¹⁴ each independently represents a lower alkyl group; A¹ represents an organic group having a valency of (n₃₁+1); and n₃₁ represents an integer of 1 to 4, and in general formula (a3-2), R represents a hydrogen atom, a halogen atom, a lower alkyl group or a halogenated lower alkyl group, and the plurality of R may be the same or different; A² represents an organic group having a valency of (n₃₂+1); and n₃₂ represents an integer of 1 to 4).

2. The positive resist composition according to claim 1, wherein A¹ in general formula (a3-1) is a hydrocarbon group of 1 to 20 carbon atoms.

3. The positive resist composition according to claim 1, wherein
the amount of said structural unit (a3) within said resin component (A), based on the combined total of all structural units constituting said resin component (A) is 1 to 10 mol %.

4. The positive resist composition according to claim 1, which further comprises a nitrogen-containing organic compound (D).

5. A method of forming a resist pattern, comprising:
forming a resist film on a substrate using a positive resist composition of any one of claim 1 to 4;
subjecting said resist film to exposure; and
developing said resist film to form a resist pattern.
